(19) United States
(12) Patent Application Publication
(10) Pub. No.: US 2013/0248830 A1
(43) Pub. Date: Sep. 26, 2013

(54) CHARGE TRANSPORT LAYERS AND FILMS CONTAINING THE SAME

(71) Applicants: DOW GLOBAL TECHNOLOGIES LLC, Midland, MI (US); ROHM AND HAAS ELECTRONIC MATERIALS KOREA LTD., Cheonan (KR)

(72) Inventors: Dean M. Welsh, Midland, MI (US); Mark E. Ondari, Midland, MI (US); Moo-Keun Chee, Seoul (KR); Bong-Ok Kim, Seoul (KR); Robert D. Froese, Midland, MI (US); Matthew M. Meyer, Canton, MI (US); Hyuck-Joo Kwon, Seoul (KR); Kyung-Hoon Choi, Hwaseong (KR); Young-Jun Cho, Seongnam (KR)

(73) Assignees: Rohm and Haas Electronic Materials Korea Ltd., Cheonan (KR); Dow Global Technologies LLC, Midland, MI (US)

(21) Appl. No.: 13/804,793

(22) Filed: Mar. 14, 2013

Related U.S. Application Data
(60) Provisional application No. 61/614,039, filed on Mar. 22, 2012.

(51) Int. Cl. H01L 51/00; H01L 51/50

(52) U.S. Cl. CPC H01L 51/0067; H01L 51/508
USPC 257/40; 544/180; 544/216; 252/500; 428/704

(57) ABSTRACT

The invention provides a film comprising at least two layers, Layer A and Layer B, and wherein Layer(A) is formed from a Composition A comprising at least one compound selected from Formula A:

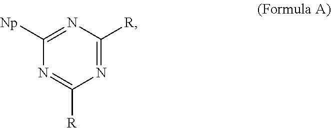

wherein Np is selected from 1-naphthyl or 2-naphthyl, and wherein each R is described herein; and
wherein Layer B is formed from a Composition B comprising at least one “HTL compound;” and
wherein Layer A is not adjacent to Layer B.

The invention also provides a composition comprising at least one compound selected from Formula A:

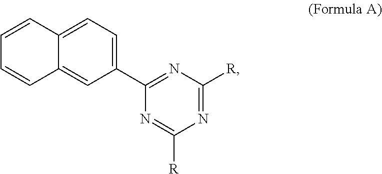

wherein each R is described herein, and wherein the compound has a Tg greater than, or equal to, 115° C.

### REFERENCE TO RELATED APPLICATIONS

The present application claims the benefit of U.S. Provisional Application No. 61/614,039, filed Mar. 22, 2012.

### BACKGROUND

Electroluminescence (EL) devices are display devices that employ stacks of films containing organic aromatic compounds as an electroluminescent layer. Such compounds are generally classified as electroluminescent materials and charge transport materials. Several properties required for such electroluminescent and charge transport compounds include high fluorescent quantum yield in solid state, high mobility of electrons and holes, chemical stability during vapor-deposition in vacuum, and the ability to form stable films. These desired features increase the lifetime of an EL device. There is a continual need for improved electroluminescent compounds and films containing the same. Applicants have discovered that certain film configurations containing certain triazine-based compounds have improved luminescent properties.

International Publication WO 2010/126270 discloses substituted triazine compounds for use as organic electroluminescent compounds, and organic electroluminescent devices employing these compounds. The compounds, when used in an electron transport layer of an organic electroluminescent device, reduce power consumption and operation voltage of said device.

U.S. Publication 2006/0251919A1 discloses organic light emitting devices (OLEDs) comprising an electroluminescent material layer, which comprises a mixture of at least two materials having different electron and hole transport capacities, and an electron transport layer comprising a triazine. Disclosed OLEDs may comprise an electron transport layer containing a triazine.

U.S. Pat. No. 6,225,467 discloses EL devices that contain an electron transport component comprised of triazine compounds. Such devices are disclosed as being capable for use in flat-panel emissive display technologies, including TV screens, computer screens, and the like. U.S. Pat. No. 7,807,276 discloses a light emitting layer for an organic LED, comprising at least one electron transporting compound, at least one hole transporting compound and a rare earth metal ion compound. The light emitting layer furthermore comprises at least one exciton conducting compound. Certain triazines are disclosed as electron transporting compounds. Also, U.S. Pat. No. 7,994,316B2 discloses 1,3,5-triazine derivatives for use as composing components of organic electroluminescent devices.

However, as discussed above, there remains a need for new film configurations containing new electroluminescent compounds, and which have improved luminescent properties. These needs and others have been met by the following invention.

### SUMMARY OF INVENTION

The invention provides, in a first aspect, a film comprising at least two layers, Layer A and Layer B, and

wherein Layer (A) is formed from a Composition A comprising at least one compound selected from Formula A:

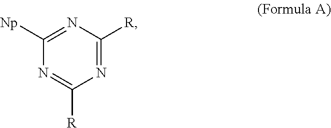

wherein Np is selected from 1-naphthyl or 2-naphthyl, and

wherein each R is independently selected from the following:
i) a (C6-C30)aryl, with or without substituent(s),
ii) a substituted or unsubstituted (C6-C30)aryl fused with one or more (C3-C30)cycloalkyl, with or without substituent(s), iii) a (C3-C30)heteroaryl with or without substituent(s),
iv) a 5- to 7-membered heterocycloalkyl with or without substituent(s),
v) a substituted or unsubstituted 5- to 7-membered heterocycloalkyl fused with one or more aromatic ring(s),
vi) a (C3-C30)cycloalkyl with or without substituent(s),
vii) a substituted or unsubstituted (C3-C30)cycloalkyl fused with one or more aromatic ring(s),
viii) an adamantyl with or without substituent(s), or
ix) a (C7-C30)bicycloalkyl with or without substituent(s); and

wherein Layer B is formed from a Composition B comprising at least one “HTL compound;” and

wherein Layer A is not adjacent to Layer B.

The invention provides, in a second aspect, a composition comprising at least one compound selected from Formula A:

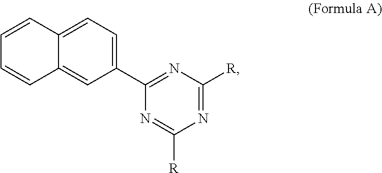

wherein each R is independently selected from the following:
i) a (C6-C30)aryl, with or without substituent(s),
ii) a substituted or unsubstituted (C6-C30)aryl fused with one or more (C3-C30)cycloalkyl, with or without substituent(s), iii) a (C3-C30)heteroaryl with or without substituent(s),
iv) a 5- to 7-membered heterocycloalkyl with or without substituent(s),
v) a substituted or unsubstituted 5- to 7-membered heterocycloalkyl fused with one or more aromatic ring(s),
vi) a (C3-C30)cycloalkyl with or without substituent(s),
vii) a substituted or unsubstituted (C3-C30)cycloalkyl fused with one or more aromatic ring(s),
viii) an adamantyl with or without substituent(s), or
ix) a (C7-C30)bicycloalkyl with or without substituent(s)

wherein the compound has a Tg greater than, or equal to, 115° C.

### DETAILED DESCRIPTION

As discussed above, the invention provides, in a first aspect, a film comprising at least two layers, Layer A and Layer B, and

wherein Layer(A) is formed from a Composition A comprising at least one compound selected from Formula A:

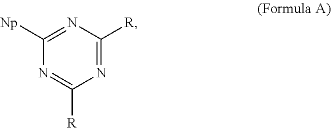

wherein Np is selected from 1-naphthyl or 2-naphthyl, and

wherein each R is independently selected from the following:
i) a (C6-C30)aryl, with or without substituent(s),
ii) a substituted or unsubstituted (C6-C30)aryl fused with one or more (C3-C30)cycloalkyl, with or without substituent(s),
iii) a (C3-C30)heteroaryl with or without substituent(s),
iv) a 5- to 7-membered heterocycloalkyl with or without substituent(s),
v) a substituted or unsubstituted 5- to 7-membered heterocycloalkyl fused with one or more aromatic ring(s),
vi) a (C3-C30)cycloalkyl with or without substituent(s),
vii) a substituted or unsubstituted (C3-C30)cycloalkyl fused with one or more aromatic ring(s),
viii) an adamantyl with or without substituent(s), or
ix) a (C7-C30)bicycloalkyl with or without substituent(s); and

wherein Layer B is formed from a Composition B comprising at least one “HTL compound;” and

wherein Layer A is not adjacent to Layer B.

In one embodiment, Composition A comprising at least two compounds selected from Formula A.

In one embodiment, Composition A comprising one compound selected from Formula A.

In one embodiment, Composition A comprises from 10 to 90 weight percent of at least one compound of Formula A, based on the weight of the composition. In a further embodiment, Composition A comprises from 50 to 90 weight percent of at least one compound of Formula A, based on the weight of the composition. In a further embodiment, Composition A comprises from 50 to 80 weight percent of at least one compound of Formula A, based on the weight of the composition.

In one embodiment, Composition A further comprises a metal quinolate. In a further embodiment, the metal quinolate is lithium quinolate.

In one embodiment, Composition A comprises from 10 to 90 weight percent of the metal quinolate, based on the weight of the composition. In a further embodiment, Composition A comprises from 10 to 50 weight percent of the metal quinolate, based on the weight of the composition. In a further embodiment, Composition A comprises from 20 to 50 weight percent of the metal quinolate, based on the weight of the composition.

In one embodiment, Composition A comprises from 10 to 90 weight percent of the metal quinolate, based on the sum weight of the compound of Formula A and the metal quinolate. In a further embodiment, Composition A comprises from 10 to 50 weight percent of the metal quinolate, based on the sum weight of the compound of Formula A and the metal quinolate. In a further embodiment, Composition A comprises from 20 to 50 weight percent of the metal quinolate, based on the sum weight of the compound of Formula A and the metal quinolate.

In one embodiment, Composition A comprises from 10 to 90 weight percent of the lithium quinolate, based on the weight of the composition. In a further embodiment, Composition A comprises from 10 to 50 weight percent of the lithium quinolate, based on the weight of the composition. In a further embodiment, Composition A comprises from 20 to 50 weight percent of the lithium quinolate, based on the weight of the composition.

In one embodiment, Composition A comprises from 10 to 90 weight percent of the lithium quinolate, based on the sum weight of the compound of Formula A and the lithium quinolate. In a further embodiment, Composition A comprises from 10 to 50 weight percent of the lithium quinolate, based on the sum weight of the compound of Formula A and the lithium quinolate. In a further embodiment, Composition A comprises from 20 to 50 weight percent of the lithium quinolate, based on the sum weight of the compound of Formula A and the lithium quinolate.

The invention also provides an article comprising at least one component formed from an inventive film. In a further embodiment, the article is an organic electroluminescent device.

An inventive film may comprise a combination of two or more embodiments described herein.

An inventive article may comprise a combination of two or more embodiments described herein.

The invention provides, in a second aspect, a composition comprising at least one compound selected from Formula A:

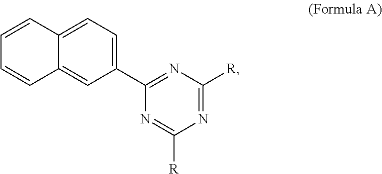

wherein each R is independently selected from the following:
i) a (C6-C30)aryl, with or without substituent(s),
ii) a substituted or unsubstituted (C6-C30)aryl fused with one or more (C3-C30)cycloalkyl, with or without substituent(s),
iii) a (C3-C30)heteroaryl with or without substituent(s),
iv) a 5- to 7-membered heterocycloalkyl with or without substituent(s),
v) a substituted or unsubstituted 5- to 7-membered heterocycloalkyl fused with one or more aromatic ring(s),
vi) a (C3-C30)cycloalkyl with or without substituent(s),
vii) a substituted or unsubstituted (C3-C30)cycloalkyl fused with one or more aromatic ring(s),
viii) an adamantyl with or without substituent(s), or
ix) a (C7-C30)bicycloalkyl with or without substituent(s)

wherein the compound has a Tg greater than, or equal to, 115° C.

In one embodiment, for Formula A, each R is independently selected from the following:
i) a (C6-C30)aryl with or without substituent(s), or
iii) a (C3-C30)heteroaryl with or without substituent(s).

In one embodiment, the compound has a Triplet Energy greater than 2.1 eV.

In one embodiment, for Formula A, each R is independently selected from the following:

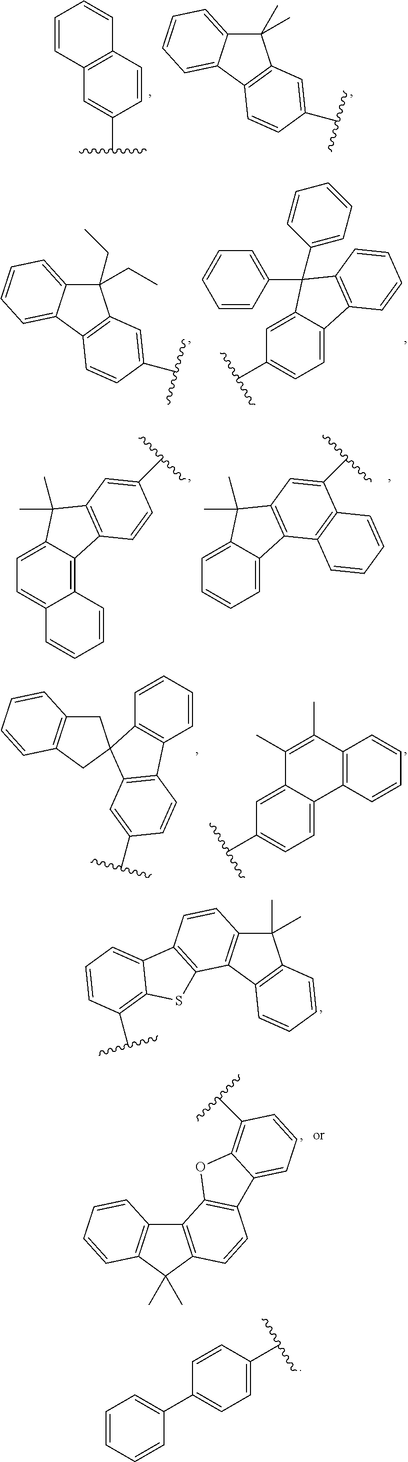

For the above structures, the external connection point of each substituent is indicated by a wavy line, as recommended by current IUPAC standards: Pure Appl. Chem., 2008, 80, 277 (Graphical representation standards for chemical structural diagrams).

In one embodiment, the compound is selected from the group consisting of the following:

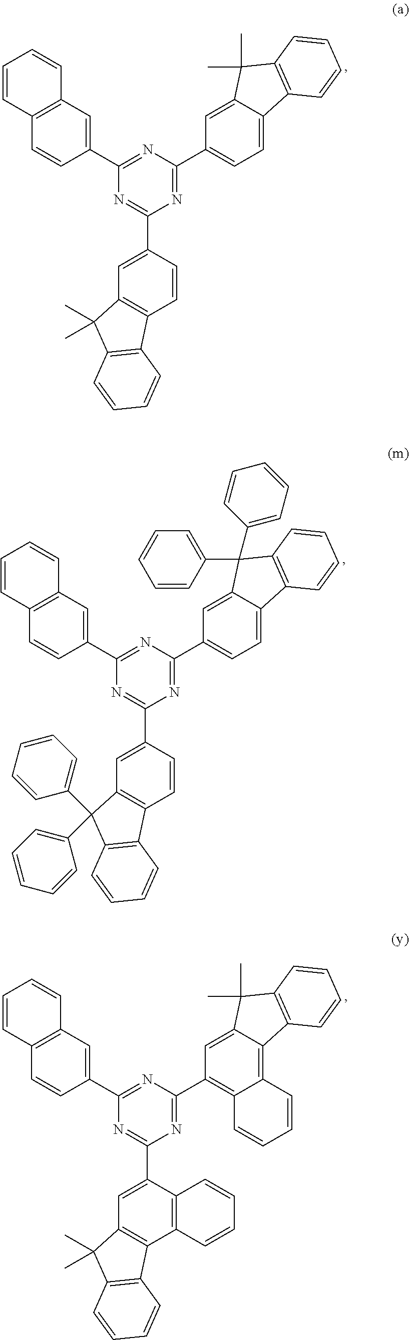 [SMILES: CC1(C)c2ccccc2-c2ccc(-c3nc(-c4ccc5c(c4)C(C)(C)c4ccccc4-5)nc(-c4ccc5ccccc5c4)n3)cc21 ; c1ccc(C2(c3ccccc3)c3ccccc3-c3ccc(-c4nc(-c5ccc6c(c5)C(c5ccccc5)(c5ccccc5)c5ccccc5-6)nc(-c5ccc6ccccc6c5)n4)cc32)cc1 ; CC1(C)c2ccccc2-c2c1cc(-c1nc(-c3ccc4ccccc4c3)nc(-c3cc4c(c5ccccc35)-c3ccccc3C4(C)C)n1)c1ccccc21]

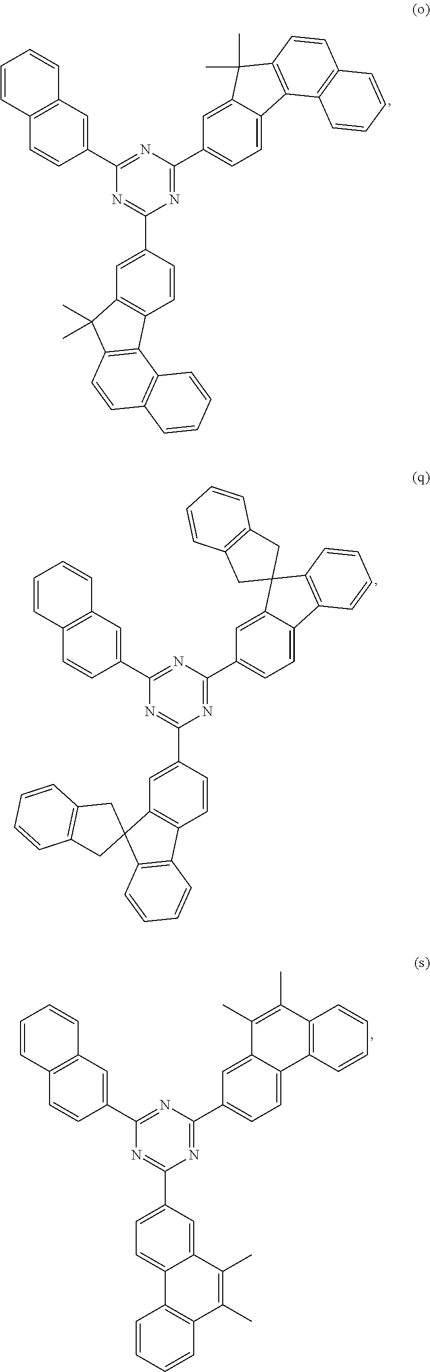 [SMILES: CC1(C)c2cc(-c3nc(-c4ccc5c(c4)C(C)(C)c4ccc6ccccc6c4-5)nc(-c4ccc5ccccc5c4)n3)ccc2-c2c1ccc1ccccc21 ; c1ccc2c(c1)CC1(C2)c2ccccc2-c2ccc(-c3nc(-c4ccc5c(c4)C4(Cc6ccccc6C4)c4ccccc4-5)nc(-c4ccc5ccccc5c4)n3)cc21 ; Cc1c(C)c2cc(-c3nc(-c4ccc5ccccc5c4)nc(-c4ccc5c(c4)c(C)c(C)c4ccccc45)n3)ccc2c2ccccc12]

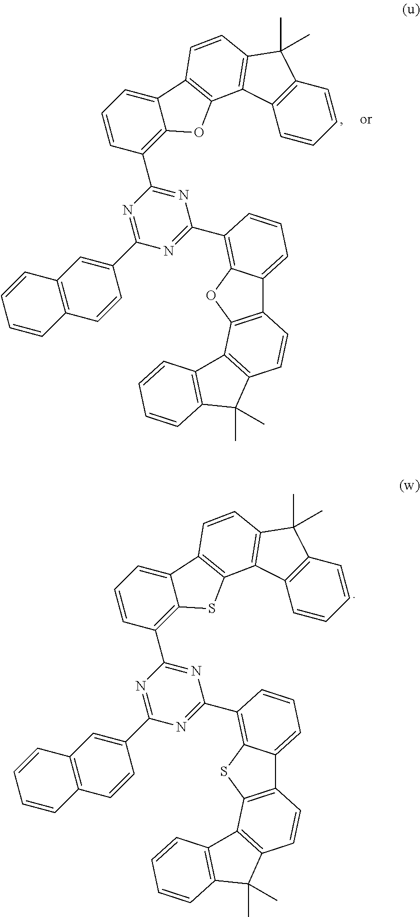 [SMILES: CC1(C)c2ccccc2-c2c1ccc1c2oc2c(-c3nc(-c4ccc5ccccc5c4)nc(-c4cccc5c4oc4c6c(ccc45)C(C)(C)c4ccccc4-6)n3)cccc21 ; CC1(C)c2ccccc2-c2c1ccc1c2sc2c(-c3nc(-c4ccc5ccccc5c4)nc(-c4cccc5c4sc4c6c(ccc45)C(C)(C)c4ccccc4-6)n3)cccc21]

In one embodiment, the compound of Formula A has a molecular weight greater than, or equal to, 450 g/mole.

In one embodiment, the compound of Formula A has a molecular weight from 450 to 800 g/mole.

In one embodiment, the compound of Formula A comprises at least one deuterium atom.

In one embodiment, the compound of Formula A has a purity greater than 99 percent.

In one embodiment, the compound of Formula A has a HOMO level from −5.3 eV to −5.9 eV.

In one embodiment, the compound of Formula A has a LUMO level from −1.80 eV to −2.05 eV.

In one embodiment, the compound of Formula A has a λ⁻ value less than, or equal to, 0.30.

In one embodiment, the composition comprising at least two compounds selected from Formula A.

In one embodiment, the composition comprising one compound selected from Formula A.

In one embodiment, the composition comprises from 10 to 90 weight percent of at least one compound of Formula A, based on the weight of the composition. In a further embodiment, the composition comprises from 50 to 90 weight percent of at least one compound of Formula A, based on the weight of the composition. In a further embodiment, the composition comprises from 50 to 80 weight percent of at least one compound of Formula A, based on the weight of the composition.

In one embodiment, the composition further comprises a metal quinolate. In a further embodiment, the metal quinolate is lithium quinolate.

In one embodiment, the composition comprises from 10 to 90 weight percent of the metal quinolate, based on the weight of the composition. In a further embodiment, the composition comprises from 10 to 50 weight percent of the metal quinolate, based on the weight of the composition. In a further embodiment, the composition comprises from 20 to 50 weight percent of the metal quinolate, based on the weight of the composition.

In one embodiment, the composition comprises from 10 to 90 weight percent of the metal quinolate, based on the sum weight of the compound of Formula A and the metal quinolate. In a further embodiment, the composition comprises from 10 to 50 weight percent of the metal quinolate, based on the sum weight of the compound of Formula A and the metal quinolate. In a further embodiment, the composition comprises from 20 to 50 weight percent of the metal quinolate, based on the sum weight of the compound of Formula A and the metal quinolate.

In one embodiment, the composition comprises from 10 to 90 weight percent of the lithium quinolate, based on the weight of the composition. In a further embodiment, the composition comprises from 10 to 50 weight percent of the lithium quinolate, based on the weight of the composition. In a further embodiment, the composition comprises from 20 to 50 weight percent of the lithium quinolate, based on the weight of the composition.

In one embodiment, the composition comprises from 10 to 90 weight percent of the lithium quinolate, based on the sum weight of the compound of Formula A and the lithium quinolate. In a further embodiment, the composition comprises from 10 to 50 weight percent of the lithium quinolate, based on the sum weight of the compound of Formula A and the lithium quinolate. In a further embodiment, the composition comprises from 20 to 50 weight percent of the lithium quinolate, based on the sum weight of the compound of Formula A and the lithium quinolate.

The invention also provides a film formed from an inventive composition. The invention also provides an article comprising at least one component formed from an inventive composition. In a further embodiment, the article is an organic electroluminescent device.

The compound of Formula A may comprise a combination of two or more embodiments described herein.

An inventive composition may comprise a combination of two or more embodiments described herein.

An inventive film may comprise a combination of two or more embodiments described herein.

An inventive article may comprise a combination of two or more embodiments described herein.

### Composition A

Composition A comprises at least one compound selected from Formula A:

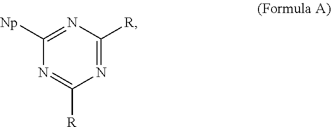

wherein Np is selected from 1-naphthyl or 2-naphthyl, and

wherein each R is independently selected from the following:
i) a (C6-C30)aryl, with or without substituent(s),
ii) a substituted or unsubstituted (C6-C30)aryl fused with one or more (C3-C30)cycloalkyl, with or without substituent(s),
iii) a (C3-C30)heteroaryl with or without substituent(s),
iv) a 5- to 7-membered heterocycloalkyl with or without substituent(s),
v) a substituted or unsubstituted 5- to 7-membered heterocycloalkyl fused with one or more aromatic ring(s),
vi) a (C3-C30)cycloalkyl with or without substituent(s),
vii) a substituted or unsubstituted (C3-C30)cycloalkyl fused with one or more aromatic ring(s),
viii) an adamantyl with or without substituent(s), or
ix) a (C7-C30)bicycloalkyl with or without substituent(s).

In one embodiment, for Formula A, each R is independently selected from the following:
i) a (C6-C30)aryl, with or without substituent(s),
ii) a substituted or unsubstituted (C6-C30)aryl fused with one or more (C3-C30)cycloalkyl, with or without substituent(s),
iii) a (C3-C30)heteroaryl with or without substituent(s),
iv) a 5- to 7-membered heterocycloalkyl with or without substituent(s),
v) a substituted or unsubstituted 5- to 7-membered heterocycloalkyl fused with one or more aromatic ring(s),
vi) a (C3-C30)cycloalkyl with or without substituent(s), or
vii) a substituted or unsubstituted (C3-C30)cycloalkyl fused with one or more aromatic ring(s).

In one embodiment, for Formula A, each R is independently selected from the following:
i) a (C6-C30)aryl, with or without substituent(s),
ii) a substituted or unsubstituted (C6-C30)aryl fused with one or more (C3-C30)cycloalkyl, with or without substituent(s),
iii) a (C3-C30)heteroaryl with or without substituent(s),
iv) a 5- to 7-membered heterocycloalkyl with or without substituent(s), or
v) a substituted or unsubstituted 5- to 7-membered heterocycloalkyl fused with one or more aromatic ring(s).

In one embodiment, for Formula A, each R is independently selected from the following:

i) a (C6-C30)aryl with or without substituent(s), or

ii) a substituted or unsubstituted (C6-C30)aryl fused with one or more (C3-C30)cycloalkyl with or without substituent(s).

In one embodiment, for Formula A, each R is independently selected from the following:
i) a (C6-C30)aryl, with or without substituent(s), or
iii) a (C3-C30)heteroaryl with or without substituent(s).

In one embodiment, for Formula A, each R is independently selected from the following:

iii) a substituted or unsubstituted (C6-C30)aryl fused with one or more (C3-C30)cycloalkyl with or without substituent(s).

In one embodiment, for Formula A, each R is independently selected from the following:

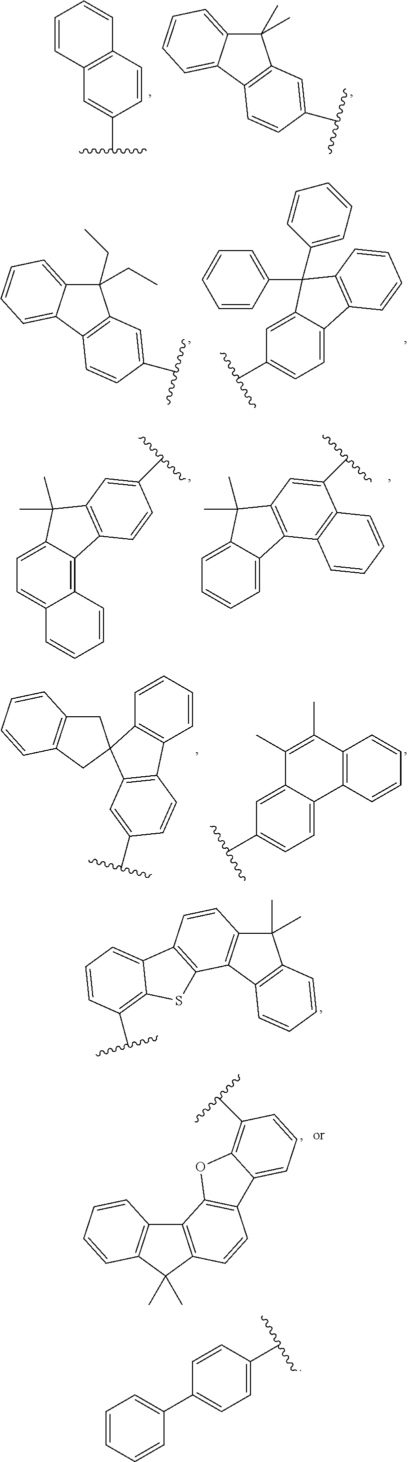

For the above structures, the external connection point of each substituent is indicated by a wavy line, as recommended by current IUPAC standards: Pure Appl. Chem., 2008, 80, 277 (Graphical representation standards for chemical structural diagrams),

In one embodiment, Formula A is selected from the following compounds (a) through (x). Each structure is shown below.

In one embodiment, Formula A is selected from the following compounds (a), (b), (m) through (z).

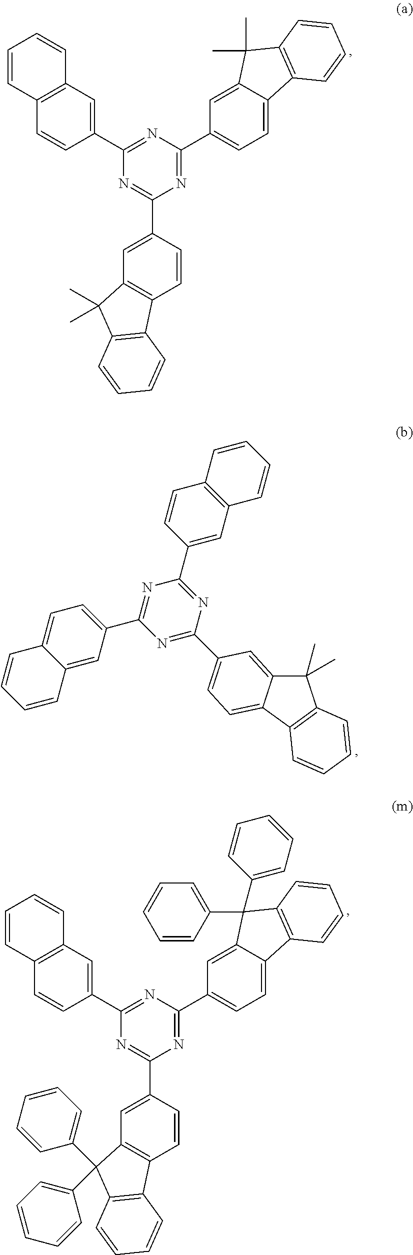 [SMILES: CC1(C)c2ccccc2-c2ccc(-c3nc(-c4ccc5c(c4)C(C)(C)c4ccccc4-5)nc(-c4ccc5ccccc5c4)n3)cc21 ; CC1(C)c2ccccc2-c2ccc(-c3nc(-c4ccc5ccccc5c4)nc(-c4ccc5ccccc5c4)n3)cc21 ; c1ccc(C2(c3ccccc3)c3ccccc3-c3ccc(-c4nc(-c5ccc6c(c5)C(c5ccccc5)(c5ccccc5)c5ccccc5-6)nc(-c5ccc6ccccc6c5)n4)cc32)cc1]

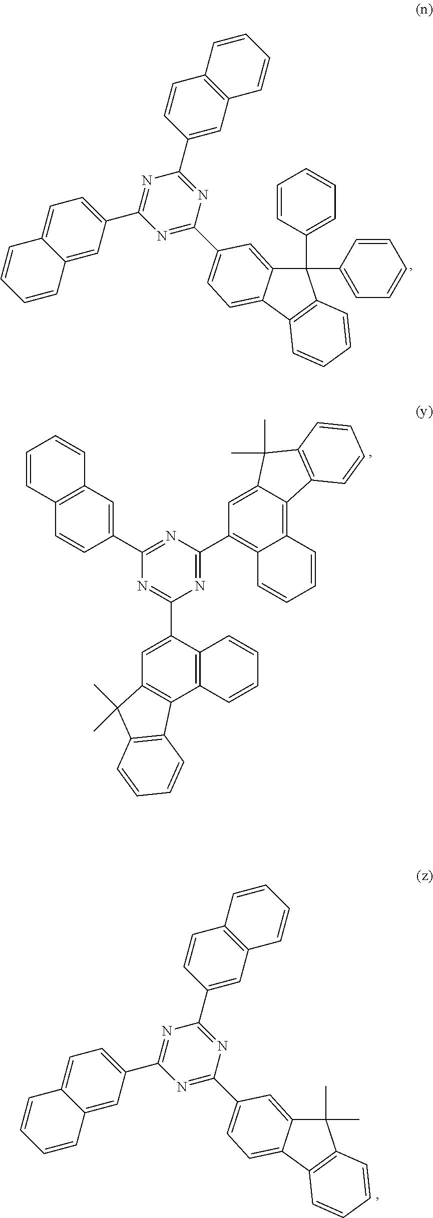 [SMILES: c1ccc(C2(c3ccccc3)c3ccccc3-c3ccc(-c4nc(-c5ccc6ccccc6c5)nc(-c5ccc6ccccc6c5)n4)cc32)cc1 ; CC1(C)c2ccccc2-c2c1cc(-c1nc(-c3ccc4ccccc4c3)nc(-c3cc4c(c5ccccc35)-c3ccccc3C4(C)C)n1)c1ccccc21 ; CC1(C)c2ccccc2-c2ccc(-c3nc(-c4ccc5ccccc5c4)nc(-c4ccc5ccccc5c4)n3)cc21]

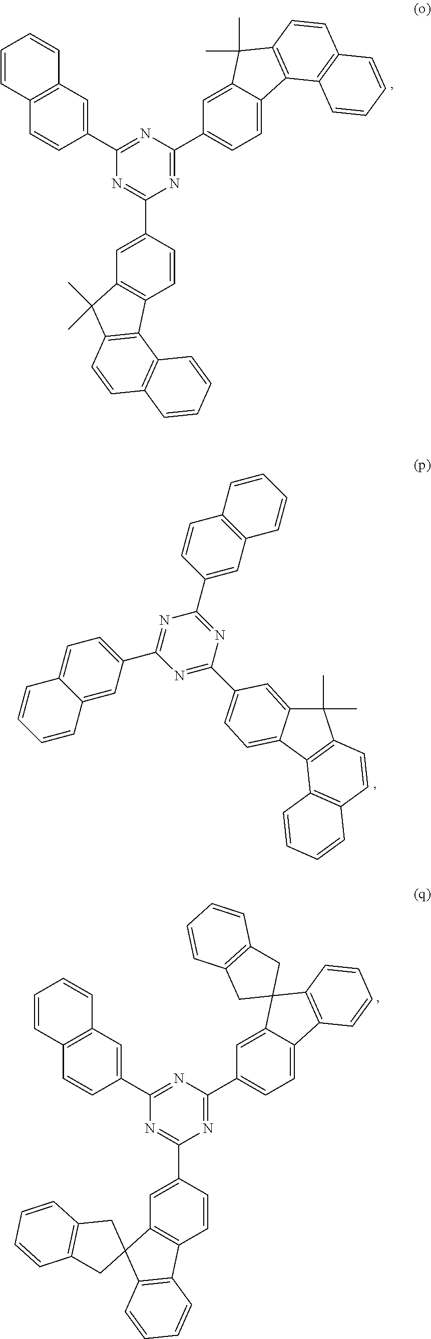 [SMILES: CC1(C)c2cc(-c3nc(-c4ccc5c(c4)C(C)(C)c4ccc6ccccc6c4-5)nc(-c4ccc5ccccc5c4)n3)ccc2-c2c1ccc1ccccc21 ; CC1(C)c2cc(-c3nc(-c4ccc5ccccc5c4)nc(-c4ccc5ccccc5c4)n3)ccc2-c2c1ccc1ccccc21 ; c1ccc2c(c1)CC1(C2)c2ccccc2-c2ccc(-c3nc(-c4ccc5c(c4)C4(Cc6ccccc6C4)c4ccccc4-5)nc(-c4ccc5ccccc5c4)n3)cc21]

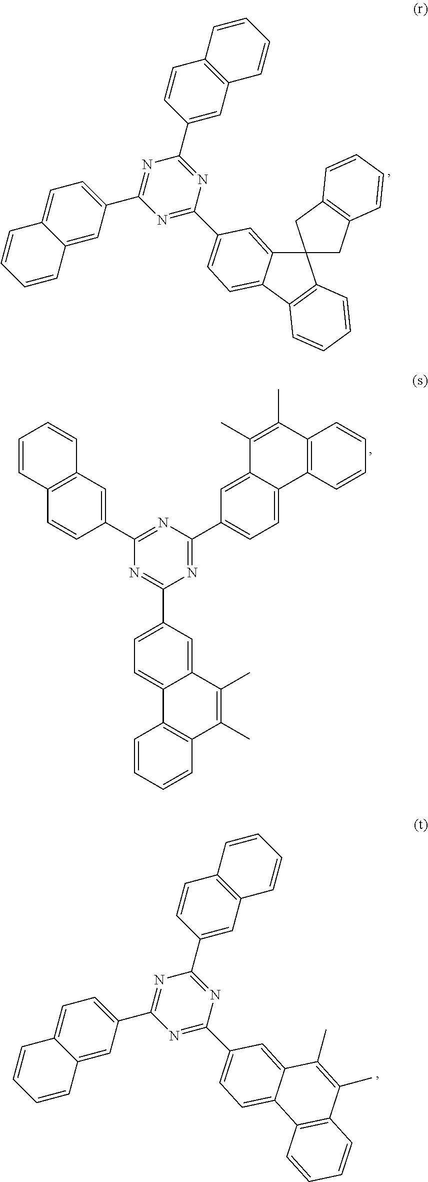 [SMILES: c1ccc2c(c1)CC1(C2)c2ccccc2-c2ccc(-c3nc(-c4ccc5ccccc5c4)nc(-c4ccc5ccccc5c4)n3)cc21 ; Cc1c(C)c2cc(-c3nc(-c4ccc5ccccc5c4)nc(-c4ccc5c(c4)c(C)c(C)c4ccccc45)n3)ccc2c2ccccc12 ; Cc1c(C)c2cc(-c3nc(-c4ccc5ccccc5c4)nc(-c4ccc5ccccc5c4)n3)ccc2c2ccccc12]

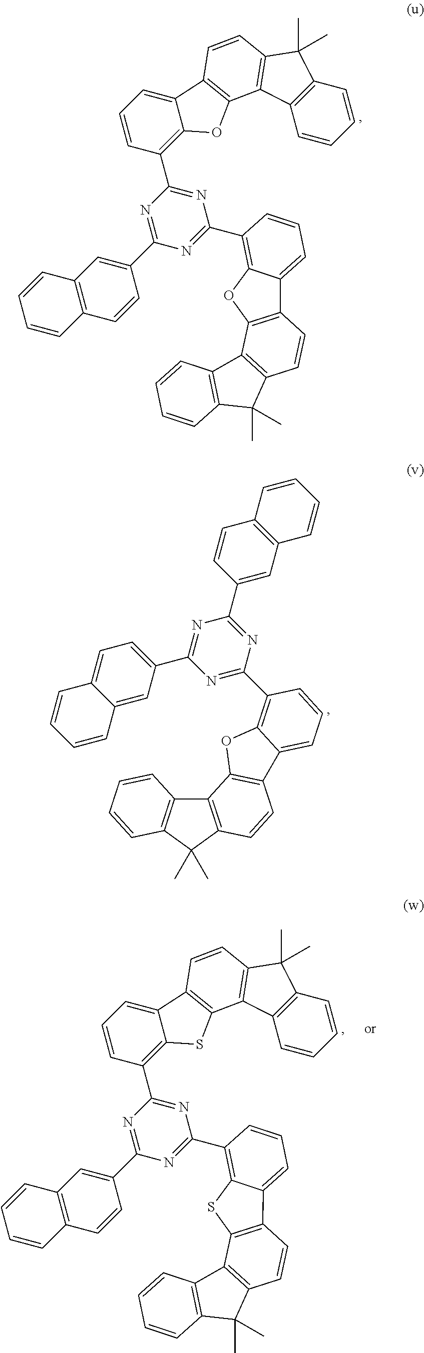 [SMILES: CC1(C)c2ccccc2-c2c1ccc1c2oc2c(-c3nc(-c4ccc5ccccc5c4)nc(-c4cccc5c4oc4c6c(ccc45)C(C)(C)c4ccccc4-6)n3)cccc21 ; CC1(C)c2ccccc2-c2c1ccc1c2oc2c(-c3nc(-c4ccc5ccccc5c4)nc(-c4ccc5ccccc5c4)n3)cccc21 ; CC1(C)c2ccccc2-c2c1ccc1c2sc2c(-c3nc(-c4ccc5ccccc5c4)nc(-c4cccc5c4sc4c6c(ccc45)C(C)(C)c4ccccc4-6)n3)cccc21]

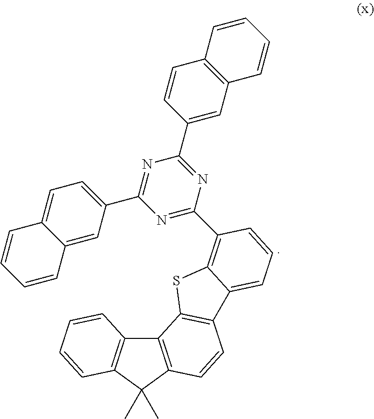 [SMILES: CC1(C)c2ccccc2-c2c1ccc1c2sc2c(-c3nc(-c4ccc5ccccc5c4)nc(-c4ccc5ccccc5c4)n3)cccc21]

In one embodiment, Formula A is selected from the following compounds (a) through (l):

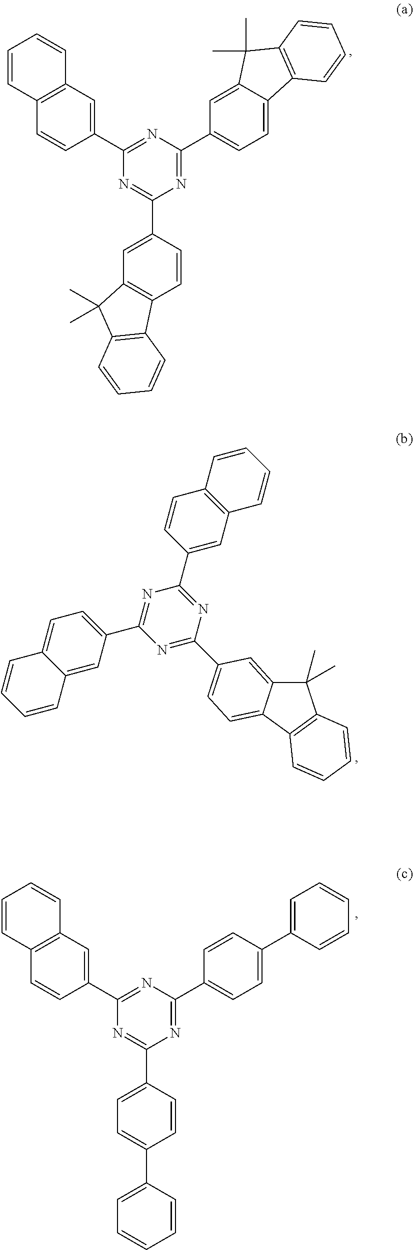 [SMILES: CC1(C)c2ccccc2-c2ccc(-c3nc(-c4ccc5c(c4)C(C)(C)c4ccccc4-5)nc(-c4ccc5ccccc5c4)n3)cc21 ; CC1(C)c2ccccc2-c2ccc(-c3nc(-c4ccc5ccccc5c4)nc(-c4ccc5ccccc5c4)n3)cc21 ; c1ccc(-c2ccc(-c3nc(-c4ccc(-c5ccccc5)cc4)nc(-c4ccc5ccccc5c4)n3)cc2)cc1]

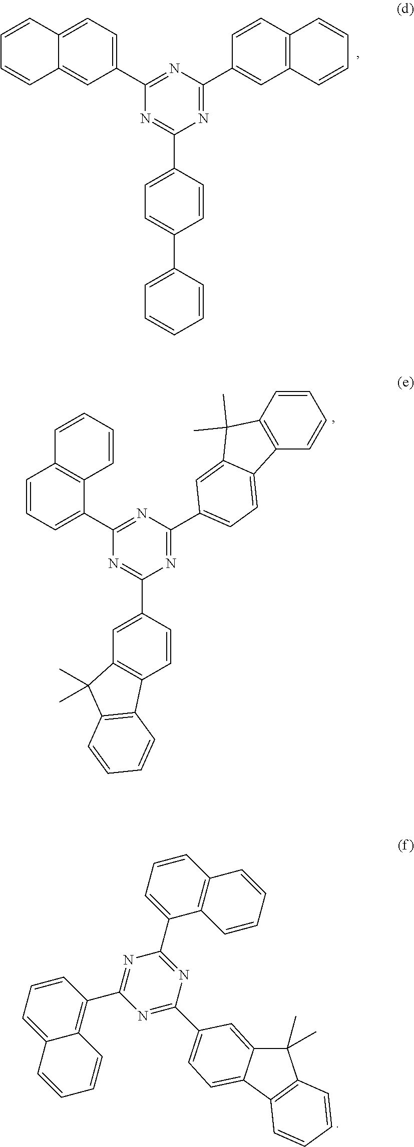 [SMILES: c1ccc(-c2ccc(-c3nc(-c4ccc5ccccc5c4)nc(-c4ccc5ccccc5c4)n3)cc2)cc1 ; CC1(C)c2ccccc2-c2ccc(-c3nc(-c4ccc5c(c4)C(C)(C)c4ccccc4-5)nc(-c4cccc5ccccc45)n3)cc21 ; CC1(C)c2ccccc2-c2ccc(-c3nc(-c4cccc5ccccc45)nc(-c4cccc5ccccc45)n3)cc21]

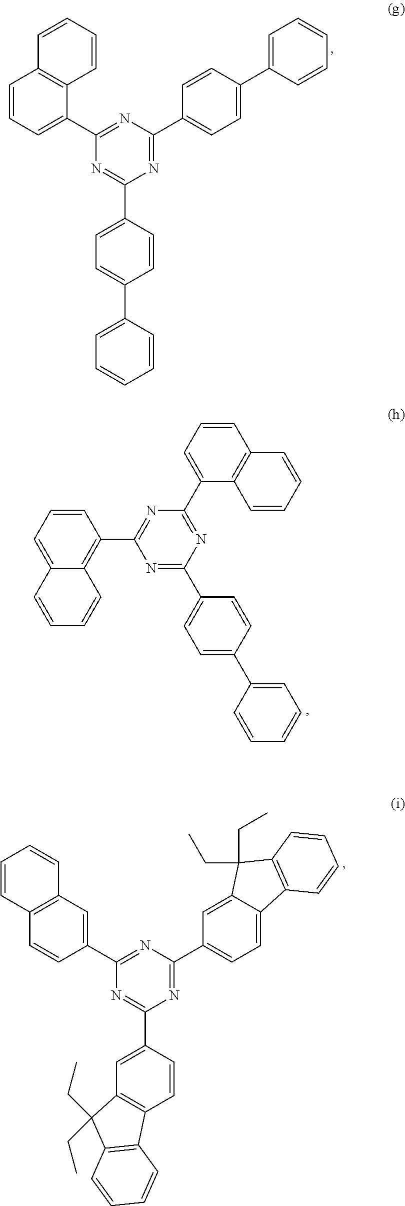 [SMILES: c1ccc(-c2ccc(-c3nc(-c4ccc(-c5ccccc5)cc4)nc(-c4cccc5ccccc45)n3)cc2)cc1 ; c1ccc(-c2ccc(-c3nc(-c4cccc5ccccc45)nc(-c4cccc5ccccc45)n3)cc2)cc1 ; CCC1(CC)c2ccccc2-c2ccc(-c3nc(-c4ccc5c(c4)C(CC)(CC)c4ccccc4-5)nc(-c4ccc5ccccc5c4)n3)cc21]

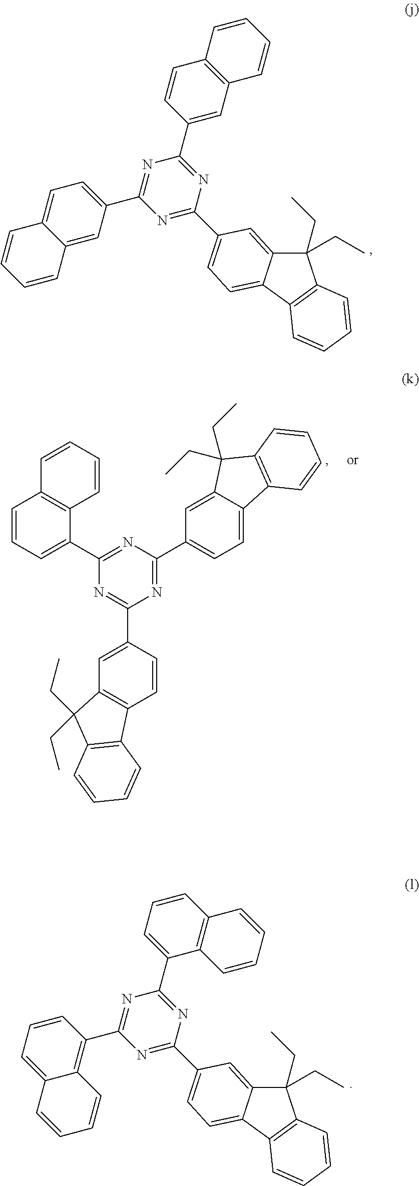 [SMILES: CCC1(CC)c2ccccc2-c2ccc(-c3nc(-c4ccc5ccccc5c4)nc(-c4ccc5ccccc5c4)n3)cc21 ; CCC1(CC)c2ccccc2-c2ccc(-c3nc(-c4ccc5c(c4)C(CC)(CC)c4ccccc4-5)nc(-c4cccc5ccccc45)n3)cc21 ; CCC1(CC)c2ccccc2-c2ccc(-c3nc(-c4cccc5ccccc45)nc(-c4cccc5ccccc45)n3)cc21]

In one embodiment, Formula A is selected from the following compounds (a), (b), (e), (f), (i), (j), (k), or (l):

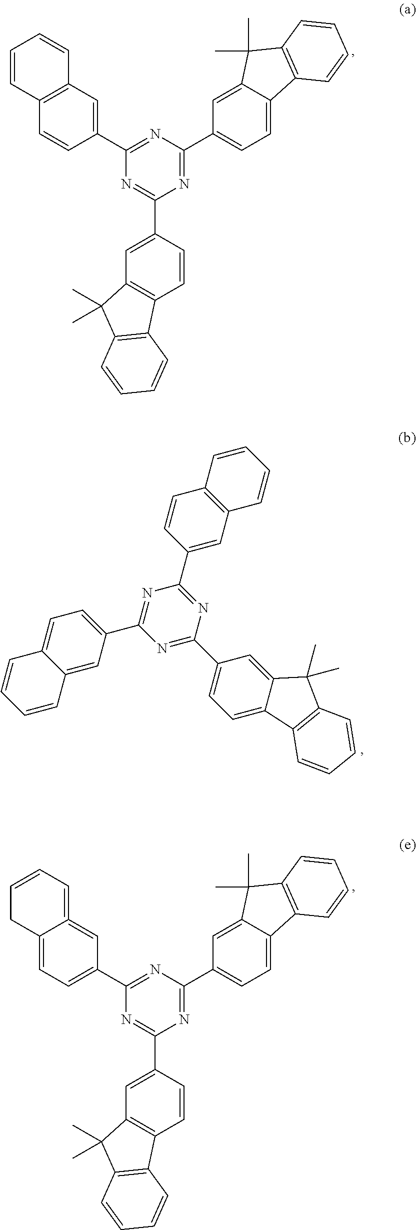

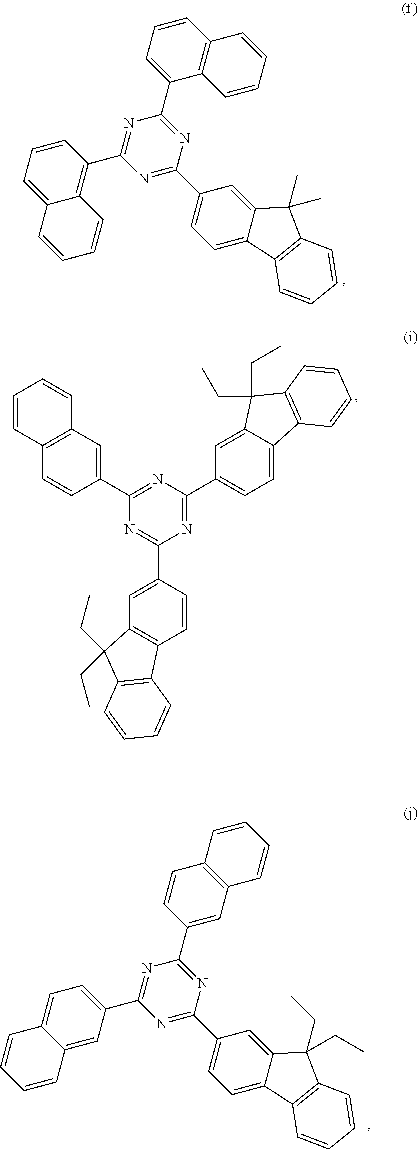 [SMILES: CC1(C)c2ccccc2-c2ccc(-c3nc(-c4cccc5ccccc45)nc(-c4cccc5ccccc45)n3)cc21 ; CCC1(CC)c2ccccc2-c2ccc(-c3nc(-c4ccc5c(c4)C(CC)(CC)c4ccccc4-5)nc(-c4ccc5ccccc5c4)n3)cc21 ; CCC1(CC)c2ccccc2-c2ccc(-c3nc(-c4ccc5ccccc5c4)nc(-c4ccc5ccccc5c4)n3)cc21]

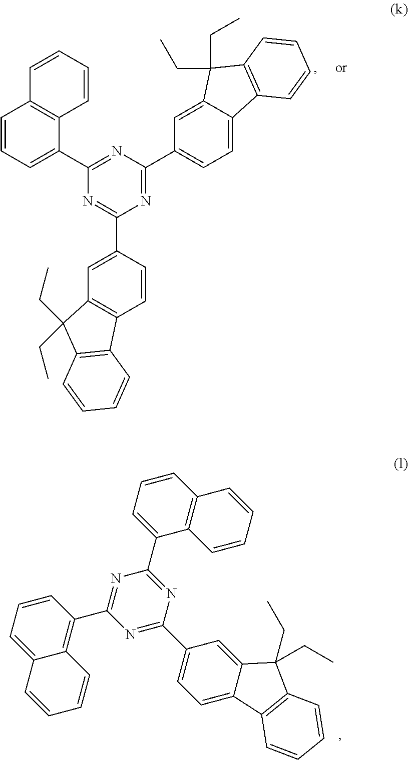 [SMILES: CCC1(CC)c2ccccc2-c2ccc(-c3nc(-c4ccc5c(c4)C(CC)(CC)c4ccccc4-5)nc(-c4cccc5ccccc45)n3)cc21 ; CCC1(CC)c2ccccc2-c2ccc(-c3nc(-c4cccc5ccccc45)nc(-c4cccc5ccccc45)n3)cc21]

In one embodiment, Formula A is selected from the following compounds (a), (b), (e), or (f):

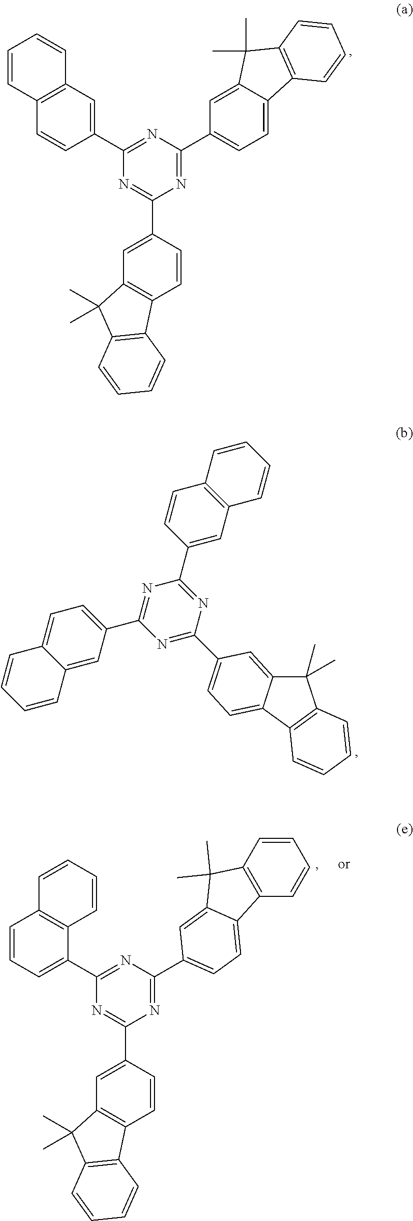 [SMILES: CC1(C)c2ccccc2-c2ccc(-c3nc(-c4ccc5c(c4)C(C)(C)c4ccccc4-5)nc(-c4ccc5ccccc5c4)n3)cc21 ; CC1(C)c2ccccc2-c2ccc(-c3nc(-c4ccc5ccccc5c4)nc(-c4ccc5ccccc5c4)n3)cc21 ; CC1(C)c2ccccc2-c2ccc(-c3nc(-c4ccc5c(c4)C(C)(C)c4ccccc4-5)nc(-c4cccc5ccccc45)n3)cc21]

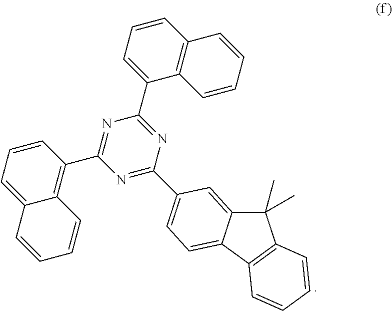 [SMILES: CC1(C)c2ccccc2-c2ccc(-c3nc(-c4cccc5ccccc45)nc(-c4cccc5ccccc45)n3)cc21]

In one embodiment, Formula A is selected from the following compounds (a), (m), (e), (o), (q), (s), (u) or (w). Each structure is shown above.

In one embodiment, the compound has a Triplet Energy greater than 2.1 eV.

In one embodiment, the compound has a glass transition temperature (Tg) greater than, or equal to, 115° C.

In one embodiment, the compound has a Triplet Energy greater than 2.1 eV.

In one embodiment, the compound of Formula A has a molecular weight greater than, or equal to, 450 g/mole.

In one embodiment, the compound of Formula A has a molecular weight from 450 to 800 g/mole.

In one embodiment, the compound of Formula A comprises at least one deuterium atom.

In one embodiment, the compound of Formula A has a purity greater than 99 percent.

In one embodiment, the compound of Formula A has a HOMO level from −5.3 eV to −5.9 eV.

In one embodiment, the compound of Formula A has a LUMO level from −1.80 eV to −2.05 eV.

In one embodiment, the compound of Formula A has a λ⁻ value less than, or equal to, 0.30.

The compound of Formula A may comprise a combination of two or more embodiments described herein.

Composition A may comprise a combination of two or more embodiments described herein.

Layer A formed from Composition A may comprise a combination of two or more embodiment described herein.

The inventive compounds may be used as charge transporting layers and other layers in electronic devices, such as OLED devices. For example, the inventive compounds may be used as charge blocking layers and charge generation layers.

### Composition B

Composition B comprises at least one “HTL compound.” An HTL compound is a material which transports holes with a low driving voltage. High hole mobility is recommended. The HTL is used to help blocks passage of electrons transported by the emitting layer. Small electron affinity is typically required to block electrons. The HTL should desirably have larger triplets to block exciton migrations from an adjacent EML layer. Examples of HTL compounds include, but are not limited to, di(p-tolyl)aminophenyl]-cyclohexane (TPAC), N,N-diphenyl-N,N-bis(3-methylphenyl)-1,1-biphenyl-4,4-diamine (TPD), and N,N′-diphenyl-N,N′-bis(1-naphthyl)-(1,1′-biphenyl)-4,4′-diamine (NPB).

In one embodiment, the HTL compound is selected from di(p-tolyl)amino-phenyl]cyclohexane (TPAC), N,N-diphenyl-N,N-bis(3-methylphenyl)-1,1-biphenyl-4,4-diamine (TPD), or N,N′-diphenyl-N,N′-bis(1-naphthyl)-(1,1′-biphenyl)-4,4′-diamine (NPB). In a further embodiment, the HTL compound is selected from N,N-diphenyl-N,N-bis(3-methylphenyl)-1,1-biphenyl-4,4-diamine (TPD), or N,N′-diphenyl-N,N′-bis(1-naphthyl)-(1,1′-biphenyl)-4,4′-diamine (NPB). In a further embodiment, the HTL compound is N,N′-diphenyl-N,N′-bis(1-naphthyl)-(1,1′-biphenyl)-4,4′-diamine (NPB).

Preferably Composition B comprises 100 weight percent of the HTL compound, based on the weight of Composition B.

Composition B may comprise a combination of two or more embodiments described herein.

Layer B formed from Composition B may comprise a combination of two or more embodiment described herein.

### DEFINITIONS

The term “aryl” described herein represents an organic radical derived from aromatic hydrocarbon by deleting one hydrogen atom therefrom. An aryl group may be a monocyclic and/or fused ring system, each ring of which suitably contains from 4 to 7, preferably from 5 or 6 atoms. Structures wherein two or more aryl groups are combined through single bond(s) are also included. Specific examples include, but are not limited to, phenyl, naphthyl, biphenyl, anthryl, indenyl, fluorenyl, benzofluorenyl, phenanthryl, triphenylenyl, pyrenyl, perylenyl, chrysenyl, naphtacenyl, fluoranthenyl and the like, but are not restricted thereto. The naphthyl may be 1-naphthyl or 2-naphthyl, the anthryl may be 1-anthryl, 2-anthryl or 9-anthryl, and the fluorenyl may be any one of 1-fluorenyl, 2-fluorenyl, 3-fluorenyl, 4-fluorenyl and 9-fluorenyl.

The term “heteroaryl” described herein means an aryl group containing at least one heteroatom; example, B, N, O, S, P(═O), Si and P, for the aromatic cyclic backbone atoms, and carbon atom(s) for remaining aromatic cyclic backbone atoms. The heteroaryl may be a 5- or 6-membered monocyclic heteroaryl or a polycyclic heteroaryl which is fused with one or more benzene ring(s), and may be partially saturated. The structures having one or more heteroaryl group(s) bonded through a single bond are also included. The heteroaryl groups may include divalent aryl groups of which the heteroatoms are oxidized or quarternized to form N-oxides, quaternary salts, or the like. Specific examples include, but are not limited to, monocyclic heteroaryl groups, such as furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl; polycyclic heteroaryl groups, such as benzofuranyl, fluoreno[4,3-b]benzofuranyl, benzothiophenyl, fluoreno[4,3-b]benzothiophenyl, isobenzofuranyl, benzimidazolyl, benzothiazolyl, benzisothiazolyl, benzisoxazolyl, benzoxazolyl, isoindolyl, indolyl, indazolyl, benzothiadiazolyl, quinolyl, isoquinolyl, cinnolinyl, quinazolinyl, quinoxalinyl, carbazolyl, phenanthridinyl and benzodioxolyl; and corresponding N-oxides (for example, pyridyl N-oxide, quinolyl N-oxide) and quaternary salts thereof.

Substituents include, but are not limited to, the following: deuterium, halogen, (C1-C30)alkyl with or without halogen substituent(s), (C6-C30)aryl, (C3-C30)heteroaryl with or without (C6-C30)aryl substituent(s), a 5- to 7-membered heterocycloalkyl containing one or more heteroatom(s) selected from, for example, B, N, O, S, P(═O), Si and P, a 5- to 7-membered heterocycloalkyl fused with one or more aromatic ring(s), (C3-C30)cycloalkyl, (C5-C30)cycloalkyl fused with one or more aromatic ring(s), tri(C1-C30)alkylsilyl, di(C1-C30)alkyl(C6-C30)arylsilyl, tri(C6-C30)arylsilyl, adamantyl, (C7-C30)bicycloalkyl, (C2-C30)alkenyl, (C2-C30)alkynyl, cyano, carbazolyl, NR₂₁R₂₂, BR₂₃R₂₄, PR₂₅R₂₆, P(═O)R₂₇R₂₈ [wherein R₂i through R₂₈ independently represent (C1-C30)alkyl, (C6-C30)aryl or (C3-C30)heteroaryl], (C6-C30)ar(C1-C30)alkyl, (C1-C30)alkyl(C6-C30)aryl, (C1-C30)alkyloxy, (C1-C30)alkylthio, (C6-C30)aryloxy, (C6-C30)arylthio, (C1-C30)alkoxycarbonyl, (C1-C30)alkylcarbonyl, (C6-C30)arylcarbonyl, (C6-C30)aryloxycarbonyl, (C1-C30)alkoxycarbonyloxy, (C1-C30)alkylcarbonyloxy, (C6-C30)arylcarbonyloxy, (C6-C30)aryloxycarbonyloxy, carboxyl, nitro and hydroxyl; or that the adjacent substituents are linked together to form a ring. For example, a substituent may form a ring structure with one or more atoms on the backbone molecule comprising said substituent.

### EXPERIMENTAL

### Reagents and Test Methods

All solvents and reagents were obtained from commercial vendors including Sigma-Aldrich, Fisher Scientific, Acros, TCI, AK Scientific, and Alfa Aesar, were used in the highest available purities, and/or were, when necessary, recrystallized before use. Dry solvents were obtained from in-house purification/dispensing system (hexane, toluene, and tetrahydrofuran), or purchased from Sigma-Aldrich. All experiments involving “water sensitive compounds” were conducted in “oven dried” glassware, under nitrogen atmosphere, or in a glovebox. Reactions were monitored by analytical thin-layer chromatography (TLC) on precoated aluminum plates (VWR 60 F254), visualized by UV light and/or potassium permanganate staining. Flash chromatography was performed on an ISCO COMBIFLASH system with GRACERESOLV cartridges.

1H-NMR-spectra (500 MHz or 400 MHz) were obtained on a Varian VNMRS-500 or VNMRS-400 spectrometer at 30° C., unless otherwise noted. The chemical shifts were referenced to TMS (δ=0.00) in CDCl₃.

¹³C-NMR spectra (125 MHz or 100 MHz) were obtained on a Varian VNMRS-500 or VNRMS-400 spectrometer, and referenced to TMS (δ=0.00) in CDCl₃.

Routine LC/MS studies were carried out as follows. Five microliter aliquots of the sample, as “3 mg/ml solution in THF,” were injected on an AGILENT 1200SL binary gradient liquid chromatography, coupled to an AGILENT 6520 QT of, quadrupole-time of flight MS system, via a dual spray electrospray (ESI) interface operating in the PI mode. The following analysis conditions were used: column: 150×4.6 mm ID, 3.5 μm ZORBAX SB-C8; column temperature: 40° C.; mobile phase: 75/25 A/B to 15/85 A/B at 40 minutes; solvent A=0.1 v % formic acid in water; solvent B=THF; flow 1.0 mL/min; UV detection: diode array 210 to 600 nm (extracted wavelength 250,280 nm); ESI conditions: gas temperature 365° C.; gas flow—8 ml/min; capillary—3.5 kV; nebulizer—40 PSI; fragmentor—145V.

DSC measurements were determined on a TA Instruments Q2000 instrument at a scan rate of 10° C./min and in a nitrogen atmosphere for all cycles. The sample was scanned from room temperature to 300° C., cooled to −60° C., and reheated to 300° C. The glass transition temperature (T_{g}) was measured on the second heating scan. Data analysis was performed using TA Universal Analysis software. The T_{g} was calculated using an “onset-at-inflection” methodology.

All computations (orbital energies, etc.) utilized the Gaussian09 program¹. The calculations were performed with the hybrid density functional theory (DFT) method, B3LYP,² and the 6-31G* (5d) basis set.³ The singlet state calculations used the closed shell approximation, and the triplet state calculations used the open shell approximation. All values are quoted in electronvolts (eV). The HOMO and LUMO values were determined from the orbital energies of the optimized geometry of the singlet ground state. The triplet energies were determined as the difference between the total energy of the optimized triplet state and the optimized singlet state.
See also, 1. Gaussian 09, Revision A.02, Frisch, M. J.; Trucks, G. W.; Schlegel, H. B.; Scuseria, G. E.; Robb, M. A.; Cheeseman, J. R.; Scalmani, G.; Barone, V.; Mennucci, B.; Petersson, G. A.; Nakatsuji, H.; Caricato, M.; Li, X.; Hratchian, H. P.; Izmaylov, A. F.; Bloino, J.; Zheng, G.; Sonnenberg, J. L.; Hada, M.; Ehara, M.; Toyota, K.; Fukuda, R.; Hasegawa, J.; Ishida, M.; Nakajima, T.; Honda, Y.; Kitao, O.; Nakai, N.; Vreven, T.; Montgomery, Jr., J. A.; Peralta, J. E.; Ogliaro, F.; Bearpark, M.; Heyd, J. J.; Brothers, E.; Kudin, K. N.; Staroverov, V. N.; Kobayashi, R.; Normand, J.; Raghavachari, K.; Rendell, A.; Burant, J. C.; Iyengar, S. S.; Tomasi, J.; Cossi, M.; Rega, N.; Millam, J. M.; Klene, M.; Knox, J. E.; Cross, J. B.; Bakken, V.; Adamo, C.; Jaramillo, J.; Gomperts, R.; Stratmann, R. E.; Yazyev, O.; Austin, A. J.; Cammi, R.; Pomelli, C.; Ochterski, J. W.; Martin, R. L.; Morokuma, K.; Zakrzewski, V. G.; Voth, G. A.; Salvador, P.; Dannenberg, J. J.; Dapprich, S.; Daniels, A. D.; Farkas, O.; Foresman, J. B.; Ortiz, J. V.; Cioslowski, J.; Fox, D. J., Gaussian, Inc., Wallingford Conn., 2009.
2. (a) Becke, A. D. J. Chem. Phys. 1993, 98, 5648. (b) Lee, C.; Yang, W.; Parr, R. G. Phys. Rev B 1988, 37, 785. (c) Miehlich, B.; Savin, A.; Stoll, H.; Preuss, H. Chem. Phys. Lett. 1989, 157, 200.
3. (a) Ditchfield, R.; Hehre, W. J.; Pople, J. A. J. Chem. Phys. 1971, 54, 724. (b) Hehre, W. J.; Ditchfield, R.; Pople, J. A. J. Chem. Phys. 1972, 56, 2257. (c) Gordon, M. S. Chem. Phys. Lett. 1980, 76, 163.

The procedure described in the literature (J. Phys. Chem. A, 2003, 107, 5241-5251) was applied to calculate the reorganization energy (λ⁻) of each molecule which is an indicator of electron mobility.

Many of these compounds can be synthesized using a two-step procedure. The first step is typically the reaction of cyanuric chloride with two equivalents of aryl Grignard reagent to form a diarylsubstituted chlorotriazine. The final product is formed in the second step by the palladium catalyzed Suzuki coupling reaction of an aryl boronic acid or boronic ester with the diarylsubstituted chlorotriazine.

The inventive compounds can be used as charge transporting layers and other layers in the OLED device, for example, charge blocking layers and charge generation layers.

### Individual Reactions

### Synthesis of Compound 2

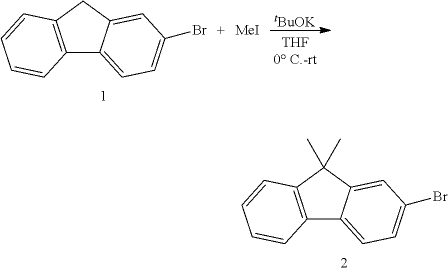 [SMILES: "tBuOK" ; "MeI" ; Brc1ccc2c(c1)Cc1ccccc1-2 ; CC1(C)c2ccccc2-c2ccc(Br)cc21]

Into a one liter, 3-neck, round bottom flask was charged 2-bromofluorene (TCI America) 1 (20 g, 82 mmol) and anhydrous tetrahydrofuran (THF) (200 mL), and the resulting solution was cooled down to 0° C. by means of an ice-water bath. Powdered potassium tert-butoxide (^{t}BuOK) (Sigma Aldrich) (27.4 g, 225 mmol, 3 equivalents) was added portion-wise (solution turns red). The solution was stirred for 10 minutes, after which time, iodomethane (MeI) (Sigma Aldrich) (34.7 g, 15.2 mmol, 225 mmol, 3 equivalents) was carefully added (exothermic process) for 10 minutes, and the reaction was allowed to warm to room temperature, while stiffing for one hour. The reaction mixture was quenched with water (200 mL), and extracted twice with ethyl acetate (EtOAc) (200 mL). EtOAc was removed, under reduced pressure, to obtain a red oil (20 mL) that was purified by flash column chromatography, using hexanes as the eluent. After solvent evaporation, under reduced pressure, a clear oil was obtained that crystallized, under vacuum, to give the desired compound 2 (22 g, 96% isolated yield and 99% pure by GC/LC-MS). ¹H NMR (400 MHz, CDCl₃) δ 7.74-7.67 (m, 1H), 7.63-7.55 (m, 2H), 7.51-7.46 (m, 1H), 7.46-7.42 (m, 1H), 7.39-7.32 (m, 2H), 1.50 (s, 6H). ¹³C NMR (101 MHz, CDCl₃) δ 155.65, 155.24, 153.20, 138.19, 138.11, 130.31, 130.04, 127.63, 127.13, 126.16, 126.11, 122.59, 121.47, 121.41, 121.33, 120.99, 120.02, 47.29, 47.07, 26.97, 26.83. Calculated mass: 272.02. found: 272.80.

### Synthesis of Compound 4

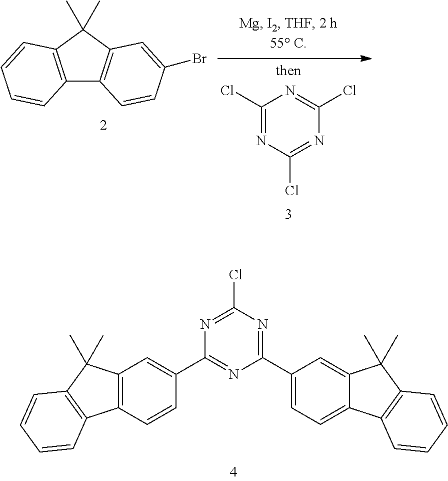 [SMILES: CC1(C)c2ccccc2-c2ccc(Br)cc21 ; Clc1nc(Cl)nc(Cl)n1 ; CC1(C)c2ccccc2-c2ccc(-c3nc(Cl)nc(-c4ccc5c(c4)C(C)(C)c4ccccc4-5)n3)cc21]

In a glove box, a glass jar was charged with 2-bromo-9,9-dimethylfluorene 2 (11 g, 40 mmol) and dry THF (100 mL). Magnesium turnings (Sigma Aldrich) (1.9 g, 80 mmol) and a crystal of iodine (Sigma Aldrich) were added into the solution, and the resulting solution was stirred at 55° C. After one hour, a GC-MS analysis of an aliquot of the reaction mixture (quenched with water and extracted with EtOAc) indicated complete conversion to the expected Grignard. This reaction mixture was added slowly (exothermic) to a solution of 1,3,5-trichlorotriazine (Sigma Aldrich) 3 (3.68 g, 20 mmol) in THF (10 mL) (note order of addition). Aliquots of the reaction were analyzed by LC-MS for one hour, after which time, more THF (40 mL) was added to the mixture, and the reaction was stirred at 55° C. overnight. LC-MS analysis of an aliquot of the product, after overnight stirring, indicated 95% conversion of starting material to the desired product. The solvent was removed, under reduced pressure, and the product was dissolved in hot chloroform, washed with water, the solvent removed under reduced pressure. The product was purified using column chromatography (10-50% chloroform/hexanes gradient) to give 9 g (90% isolated yield) of the desired product 4. ¹H NMR (400 MHz, CDCl₃) δ 8.72-8.63 (m, 4H), 7.88 (dd, J=8.0, 0.6 Hz, 2H), 7.85-7.78 (m, 2H), 7.53-7.45 (m, 2H), 7.44-7.35 (m, 4H), 1.60 (s, 12H). ¹³C NMR (101 MHz, CDCl₃) δ 173.40, 171.92, 154.92, 154.11, 144.74, 138.07, 133.34, 129.05, 128.62, 127.24, 123.55, 122.83, 120.97, 120.18, 47.12, 27.04. Calculated mass: 499.18. found: 499.37.

### Synthesis of Compound 6

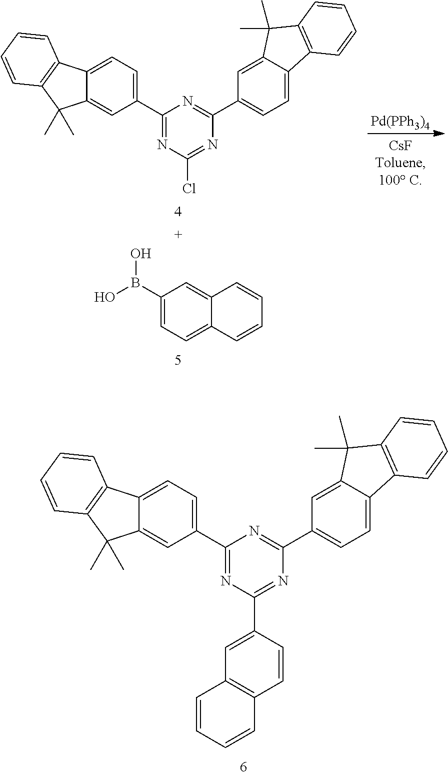 [SMILES: CC1(C)c2ccccc2-c2ccc(-c3nc(Cl)nc(-c4ccc5c(c4)C(C)(C)c4ccccc4-5)n3)cc21 ; OB(O)c1ccc2ccccc2c1 ; CC1(C)c2ccccc2-c2ccc(-c3nc(-c4ccc5c(c4)C(C)(C)c4ccccc4-5)nc(-c4ccc5ccccc5c4)n3)cc21 ; "Pd(PPh3)4"]

In a glove box, a glass jar was charged with a mixture of 3,5-bis(9,9-dimethyl-fluorenyl)-1-chlorotriazine (5 g, 10 mmol), 2-naphthylboronic acid (AK Scientific) (2.6 g, 15 mmol, 1.5 equivalents), and powdered CsF (Sigma Aldrich) (4.6 g, 30 mmol, 3 equivalents). Dry toluene (100 mL) was added, followed with Pd(PPh₃)₄ (Sigma Aldrich) (578 mg, 0.5 mmol, 5 mol %). The reaction mixture was heated to 100° C., and aliquots were periodically analyzed by LC-MS to check reaction progress. After six hours, LC-MS analysis showed 99% conversion of starting material to expected product. The reaction mixture was cooled down, diluted with chloroform (300 mL), washed with water (200 mL), and the aqueous layer extracted with chloroform (3×200 mL). After solvent removal under vacuum, the product was loaded onto an ISCO purification system, and eluted with 30% chloroform in hexanes to give 5 g (84% recovery) at 99.67% purity. ¹H NMR (400 MHz, CDCl₃) δ 9.37 (d, J=0.8 Hz, 1H), 8.87 (dt, J=5.0, 1.5 Hz, 5H), 8.19-8.11 (m, 1H), 8.06 (d, J=8.7 Hz, 1H), 7.99-7.90 (m, 3H), 7.89-7.81 (m, 2H), 7.65-7.56 (m, 2H), 7.56-7.49 (m, 2H), 7.45-7.36 (m, 4H), 1.68 (s, 12H). ¹³C NMR (101 MHz, CDCl₃) δ 171.83, 171.52, 154.80, 153.96, 143.66, 138.47, 135.68, 135.40, 133.90, 133.16, 129.97, 129.59, 128.59, 128.31, 128.25, 127.87, 127.78, 127.18, 126.41, 125.26, 123.10, 122.80, 120.82, 120.10, 47.11, 27.23. Calculated mass: 591.26. found: 591.47.

### Synthesis of Compound 8

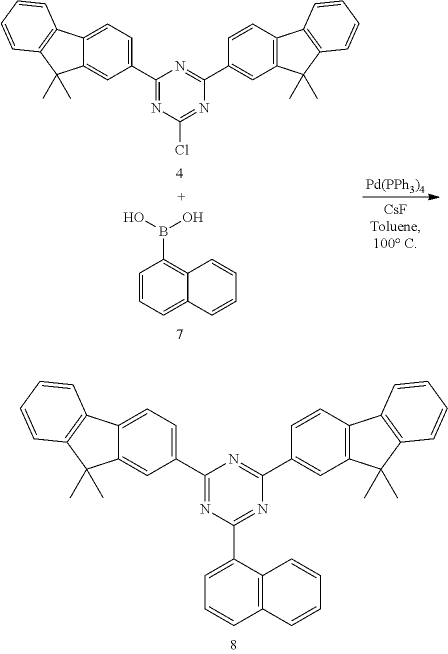 [SMILES: CC1(C)c2ccccc2-c2ccc(-c3nc(Cl)nc(-c4ccc5c(c4)C(C)(C)c4ccccc4-5)n3)cc21 ; OB(O)c1cccc2ccccc12 ; CC1(C)c2ccccc2-c2ccc(-c3nc(-c4ccc5c(c4)C(C)(C)c4ccccc4-5)nc(-c4cccc5ccccc45)n3)cc21 ; "Pd(PPh3)4"]

In a nitrogen purged glove box, a glass jar was charged with a mixture of 3,5-bis(9,9-dimethylfluorenyl)-1-chlorotriazine (3.50 g, 7.00 mmol), 1-naphthyl boronic acid (1.81 g, 10.5 mmol, 1.5 equivalents), and powdered CsF (3.19 g, 21.0 mmol, 3 equivalents). Dry toluene (100 mL) was added, followed with Pd(PPh₃)₄ (Sigma Aldrich) (0.41 g, 0.35 mmol, 5 mol %). The reaction mixture was heated to 90° C. overnight. After 18 hours, LC/MS and TLC analysis confirmed the completion of the reaction. The reaction mixture was cooled down, diluted with chloroform, washed with water, and the aqueous layer extracted with chloroform. The organic layer was dried over MgSO₄ after washing with water. The solvent was removed under reduced pressure. The dried crude product was purified using column chromatography with 40% chloroform in hexane as the eluent. After the purification, 3.20 g of compound 8 was obtained (Yield was 77.26%). ¹H NMR (400 MHz, CDCl₃) δ 9.22-9.18 (d, 1H), 8.82-8.88 (m, 4H), 8.57-8.60 (dd, 1H), 8.08-8.12 (ddd, 1H), 7.98-8.02 (ddd, 1H), 7.93-7.96 (dd, 2H), 7.83-7.88 (m, 2H), 7.69-7.74 (m, 1H), 7.57-7.68 (m, 2H), 7.50-7.56 (m, 2H), 7.36-7.44 (m, 4H), 1.66 (s, 12H). ¹³C NMR (101 MHz, CDCl₃) δ 174.15, 171.65, 154.80, 154.02, 143.78, 138.40, 135.23, 134.28, 132.16, 131.41, 130.56, 128.67, 128.58, 128.28, 127.18, 127.05, 126.29, 126.08, 125.21, 123.20, 122.81, 120.83, 120.15, 47.09, 27.15.

### Synthesis of Compound 10

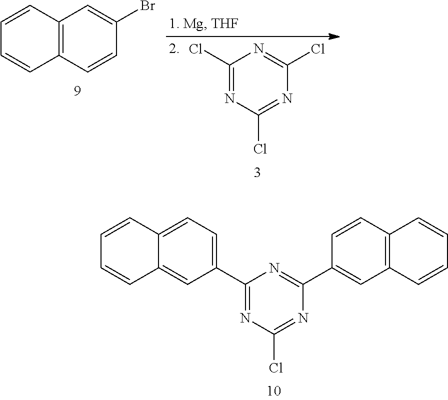 [SMILES: Brc1ccc2ccccc2c1 ; Clc1nc(Cl)nc(Cl)n1 ; Clc1nc(-c2ccc3ccccc3c2)nc(-c2ccc3ccccc3c2)n1]

In a nitrogen-filled dry box, a glass jar was charged with Mg (2.05 g, 84.5 mmol) and THF (40 mL). To this was added 2-bromonaphthalene (15.0 g, 72.4 mmol) dissolved in THF (35 mL) portionwise over 40 min with stiffing. During the slow addition the reaction began to exotherm and upon each subsequent portion addition of the aryl bromide solution the reaction bubbled vigorously. When the bubbling subsided another portion was added. Upon complete addition the reaction was allowed to stir for 30 min and an aliquot was taken and quenched with D₂O. The organic phase was collected, dried over MgSO₄, filtered and analyzed by GC. The GC trace revealed naphthalene (4.8 min) at 98.5 area % purity.

The Grignard solution was allowed to cool to room temperature, and filtered over celite, and the celite pad was washed with a minimal amount of fresh THF. A second glass jar was charged with cyanuric chloride (4.45 g, 24.1 mmol), THF (40 mL), and the contents were stirred at room temperature until homogeneous. A portion (2 eq) of the Grignard solution (47 mL) was added slowly over 20 minutes, after which an aliquot was taken, quenched with water and analyzed by HPLC. Upon which time the reaction was quenched with H2O (60 mL) and extracted with CH₂Cl₂. An emulsion was formed which was filtered over celite. The organic layer was dried over MgSO₄, filtered and concentrated to dryness by rotatory evaporation, affording 8.9 g of brown solids. The solids were dissolved in THF and mixed with celite. The THF was removed by rotatory evaporation, affording chunky brown solids which were pulverized by mortar and pestle. The resulting powder was purified by flash chromatography. Fractions were combined (based on thin layer chromatography analysis) and concentrated to dryness. The residue was recrystallized by dissolving in CH₂Cl₂ and adding hexanes until cloudy. The cloudy solution was placed in the freezer (−15° C.) overnight, affording white solids. The solids were collected by filtration, and dried in a vacuum oven (50° C.), affording 1.9 g (11% yield) of precursor compound 10. ¹H NMR (500 MHz, Chloroform-d) δ 9.21 (s, 2H), 8.66 (d, J=8.6 Hz, 2H), 8.07 (d, J=7.8 Hz, 2H), 7.98 (d, J=8.5 Hz, 2H), 7.91 (d, J=7.8 Hz, 2H), 7.74-7.47 (m, 4H). ¹³C NMR (126 MHz, Chloroform-d) δ 173.69, 172.39, 136.36, 133.26, 132.08, 131.24, 129.91, 128.76, 128.65, 128.05, 126.90, 125.20.

### Synthesis of Compound 12

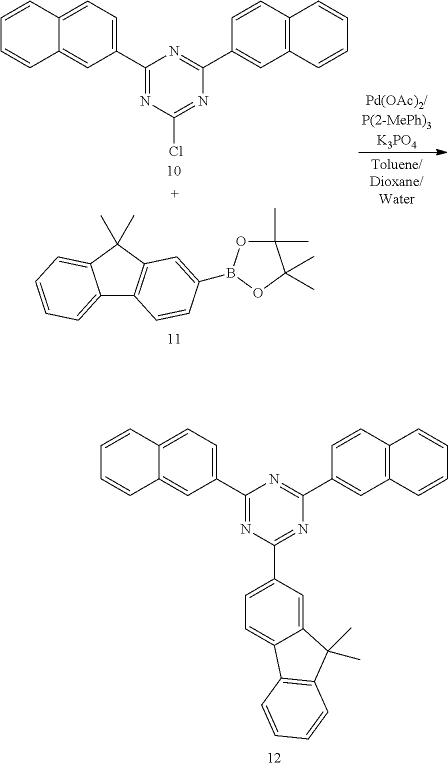 [SMILES: Clc1nc(-c2ccc3ccccc3c2)nc(-c2ccc3ccccc3c2)n1 ; "Pd(OAc)2/P(2-MePh)3K3PO4" ; CC1(C)c2ccccc2-c2ccc(B3OC(C)(C)C(C)(C)O3)cc21 ; CC1(C)c2ccccc2-c2ccc(-c3nc(-c4ccc5ccccc5c4)nc(-c4ccc5ccccc5c4)n3)cc21]

In a nitrogen-filled dry box a glass jar was loaded with 2-chloro-4,6-di(naphthalene-2-yl)-1,3,5-triazine (1.90 g, 5.17 mmol), 2-(9,9-dimethyl-9H-fluoren-2-yl)-4,4,5,5-tetramethyl-1,3,2-dioxaborolane (2.32 g, 7.23 mmol), K₃PO₄ (3.84 g, 18.1 mmol), Pd(OAc)₂ (0.058 g, 0.26 mmol) and tri-o-tolylphosphine (0.472 g, 1.55 mmol). To this powder mixture was added toluene (50 mL), 1,4-dioxane (50 mL) and degassed H₂O (1 mL). This slurry was heated and stirred at 80° C. for 2 h becoming a yellow/green slurry. An aliquot was analyzed by HPLC, showing no detectable level of di(naphthyl)mono(chloro)triazine (8.27 min) The reaction was allowed to cool to RT and concentrated to dryness and the residue was dissolved in methylene chloride. The methylene chloride layer was washed with water, dried over MgSO₄ and concentrated to dryness by rotatory evaporation. The product was purified by column chromatography. The product was recrystallized from methylene chloride/hexanes. The solids were collected and rinsed with fresh hexanes. The solids were dried in a vacuum oven affording 2.3 g of white solids, and “2.1 g of the solids” was sublimed, affording 1.1 g of off-white solids 12 (99.3% pure by LC-MS analysis). ¹H NMR (500 MHz, Chloroform-d) δ 9.41-9.33 (m, 2H), 8.97-8.79 (m, 4H), 8.22-8.07 (m, 2H), 8.04 (d, J=8.7 Hz, 2H), 7.99-7.90 (m, 3H), 7.88-7.82 (m, 1H), 7.65-7.56 (m, 4H), 7.55-7.48 (m, 1H), 7.44-7.37 (m, 2H), 1.69 (s, 6H); ¹³C NMR (126 MHz, cdcl₃) δ=172.28, 171.95, 155.15, 154.30, 143.97, 138.74, 136.01, 135.73, 134.22, 133.51, 130.25, 129.79, 128.87, 128.49, 128.46, 128.06, 127.95, 127.37, 126.58, 125.51, 123.36, 122.96, 121.01, 120.26, 47.35, 27.43.

### Modeling of Inventive and Comparative Compounds

Tables 1 and 2 list energy levels for comparative and inventive compounds, respectively.

TABLE 1
Modeling Data for Comparative Compounds

| | | Molecular | | | |
|---|---|---|---|---|---|
| | | Weight | HOMO | LUMO | |
| Number | Structure | (g/mole) | (eV)^{a} | (eV)^{b} | (λ)^{c} |
| A | 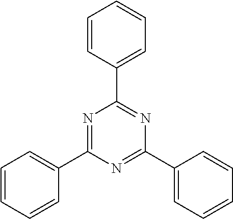 [SMILES: c1ccc(-c2nc(-c3ccccc3)nc(-c3ccccc3)n2)cc1] | 309.36 | −6.65 | −1.80 | 0.28 |
| B | 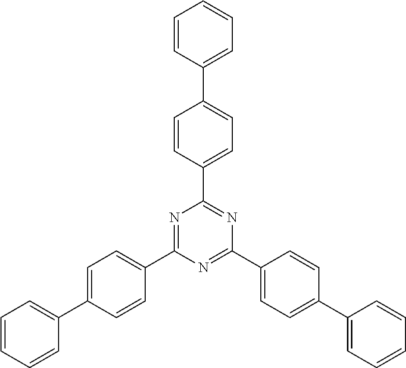 [SMILES: c1ccc(-c2ccc(-c3nc(-c4ccc(-c5ccccc5)cc4)nc(-c4ccc(-c5ccccc5)cc4)n3)cc2)cc1] | 537.65 | −6.10 | −1.89 | 0.24 |
| C | 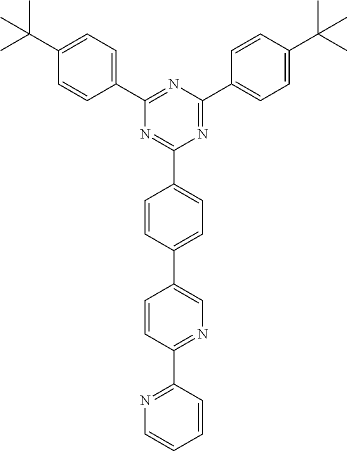 [SMILES: CC(C)(C)c1ccc(-c2nc(-c3ccc(-c4ccc(-c5ccccn5)nc4)cc3)nc(-c3ccc(C(C)(C)C)cc3)n2)cc1] | 575.74 | −6.12 | −1.94 | 0.36 |

^{a,b}The HOMO and LUMO level calculated as described above.
^{c}The reorganization energy calculated as described above.

TABLE 2
Modeling Data and Thermal Analysis for Inventive Compounds

| | | Molecular | | | Triplet | | |
|---|---|---|---|---|---|---|---|
| | | Weight | HOMO | LUMO | Energy | | T_{g} |
| Number | Structure | (g/mole) | (eV)^{a} | (eV)^{b} | (eV)^{c} | (λ)^{d} | (° C.)^{e} |
| 6 | 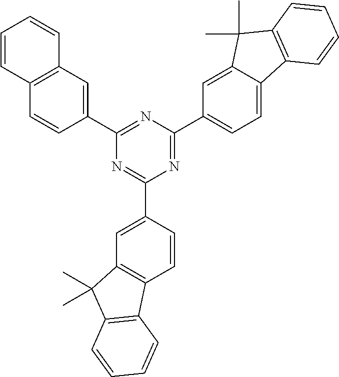 [SMILES: CC1(C)c2ccccc2-c2ccc(-c3nc(-c4ccc5c(c4)C(C)(C)c4ccccc4-5)nc(-c4ccc5ccccc5c4)n3)cc21] | 591.74 | −5.81 | −1.89 | 2.59 | 0.18 | 119 |
| 8 | 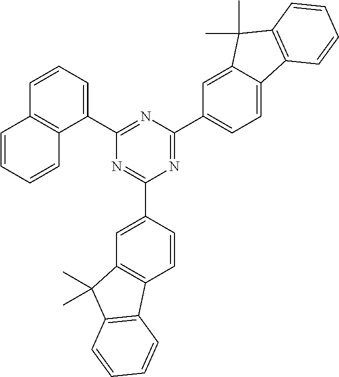 [SMILES: CC1(C)c2ccccc2-c2ccc(-c3nc(-c4ccc5c(c4)C(C)(C)c4ccccc4-5)nc(-c4cccc5ccccc45)n3)cc21] | 591.74 | −5.79 | −1.92 | 2.33 | 0.22 | 110 |
| 12 | 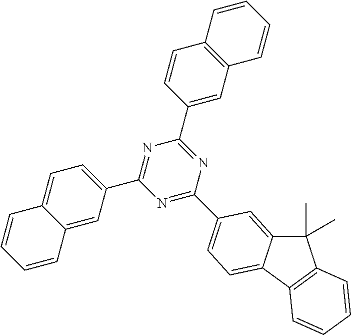 [SMILES: CC1(C)c2ccccc2-c2ccc(-c3nc(-c4ccc5ccccc5c4)nc(-c4ccc5ccccc5c4)n3)cc21] | 525.64 | −5.79 | −1.89 | 2.38 | 0.25 | 98 |

^{a,b}The HOMO and LUMO level calculated as described above.
^{c}The triplet energy calculated as described above.
^{d}The reorganization energy calculated as described above.
^{e}The glass transition temperature measured by DSC as described above.

As opposed to the comparative compounds, the inventive compounds exhibit the preferred combination of the proper LUMO energy (from −1.8 to −2.05 eV), HOMO energy (from −5.3 to −5.9 eV) and low reorganization energy (λ⁻) values (<0.30). Inventive compound 6 is the most preferred, because it has the desired Tg>115° C., which leads to a more robust device when subjected to higher temperatures during device fabrication and operation. Comparative compounds A and B are also known to be crystalline compounds lacking a glass transition (Zeng, L,; Lee, T.; Merkel, P. B.; Chen, S. H. J. Mater. Chem. 2009, 19, 8772./Ishi-I, T.; Yaguma, K.; Thiemann, T.; Yashima, M.; Ueno, K.; Mataka, S. Chem. Lett. 2004, 33, 1244), making them less desirable, since stable, amorphous glasses are desired for stable film morphology during device fabrication and operation. Comparative compound A also falls outside the desired molecular weight range from 450 to 800 g/mol.

### OLED Device Fabrication and Testing

All organic materials were purified by sublimation before deposition. OLEDs were fabricated onto an ITO coated glass substrate that served as the anode, and topped with an aluminum cathode. All organic layers were thermally deposited by chemical vapor deposition, in a vacuum chamber, with a base pressure of <10⁻⁷ ton. The deposition rates of organic layers were maintained at 0.1-0.05 nm/s. The aluminum cathode was deposited at 0.5 nm/s. The active area of the OLED device was “3 mm×3 mm,” as defined by the shadow mask for cathode deposition. The glass substrate (20 mm by 20 mm) was available from Samsung Corning with ITO layer thickness of 1500 Angstrom. A five layer film was formed with the following configuration: HIL(600A)/NPB(200A)/“ADN doped with 2% of Dopant” (350A)/“ETL:Liq” (300A)/Lig(10A). See Table 3.

Each cell, containing HIL, HTL, EML host, EML dopant, ETL, or EIL, was placed inside a vacuum chamber until it reached 10⁻⁶ ton. To evaporate each material, a controlled current was applied to the cell, containing the material, to raise the temperature of the cell. An adequate temperature was applied to keep the evaporation rate of the materials constant throughout the evaporation process. For the HIL layer, N1,N1′-([1,1′-biphenyl]-4,4′-diyl)bis(N1-(naphthalen-1-yl)-N4,N4′-diphenylbenzene-1,4-diamine) was evaporated at a constant 1 A/s rate, until the thickness of the layer reached 600 Angstrom. Simultaneously, the N4,N4′-di(naphthalen-1-yl)-N4,N4′-diphenyl-[1,1′-biphenyl]-4,4′-diamine (NPB) layer was evaporated at a constant 1 A/s rate, until the thickness reached 200 Angstrom. For the EML layer, 9,10-di(naphthalen-2-yl)anthracene (ADN, host) and (E)-4,4′-(ethene-1,2-diyl)bis(N,N-diphenylaniline) (DPAVB, dopant) were co-evaporated until the thickness reached 350 Angstrom. The deposition rate for host material was 0.98 A/s, and the deposition for the dopant material was 0.02 A/s, resulting in a 2% doping of the host material. For the ETL layer, the ETL compounds were co-evaporated with lithium quinolate(Liq), until the thickness reached 300 Angstrom. The evaporation rate for the ETL compounds and Liq was 0.5 A/s. Alq3 was used as a reference material to compare with the inventive compounds. Alq3 was evaporated solely at 1 A/s rate until 300 Angstrom. Finally, “20 Angstrom” of a thin electron injection layer (Liq) was evaporated at a 0.2 A/s rate.

The current-voltage-brightness (J-V-L) characterizations for the OLED devices were performed with a source measurement unit (KEITHLY 238) and a luminescence meter (MINOLTA CS-100A). EL spectra of the OLED devices were collected by a calibrated CCD spectrograph. The results are shown in Table 4 below. The inventive film containing an ETL (Electron Transfer Layer) film layer containing Compounds 6, 8, and 12 showed better (lower) turn on voltage and better (higher) luminous efficiency.

TABLE 3

| | | Commercial |
|---|---|---|
| | Name | name |
| Hole Injection | N1,N1′-([1,1′-biphenyl]-4,4′- | See |
| Material | diyl)bis(N1-(naphthalen-1-yl)- | KR 10-2008- |
| | N4,N4-diphenylbenzene-1,4- | 0041682 |
| | diamine) | |
| Hole Transporting | N4,N4′-di(naphthalen-1-yl)-N4,N4′- | NPB |
| Material | diphenyl-[1,1′-biphenyl]-4,4′-diamine | |
| Fl Blue Host | 9,10-di(naphthalen-2-yl)anthracene | ADN |
| Fl Blue Dopant | (E)-4,4′-(ethene-1,2-diyl)bis(N,N- | DPAVB |
| | diphenylaniline) | |
| Ref ETL | tris(8-hydroxyquinolinato)aluminium | Alq3 |
| Electron Injection | lithium quinolate | Liq |
| Material | | |

TABLE 4

| | | Current | Luminous | |
|---|---|---|---|---|
| | Voltage @ | Density @ | Efficiency @ | |
| | 1000 nit | 1000 nit | 1000 nit | CIE |
| | [V] | [mA/cm2] | [Cd/A] | (X, Y) |
| Alq3(ref) | 6.6 | 22.4 | 4.0 | 149, 150 |
| Compound 6: Liq | 5.0 | 14.8 | 5.4 | 149, 149 |
| Compound 8: Liq | 5.2 | 17.3 | 5.2 | 149, 150 |
| Compound 12: Liq | 5 | 17.6 | 5.4 | 149, 149 |

1. A film comprising at least two layers, Layer A and Layer B, and
wherein Layer(A) is formed from a Composition A comprising at least one compound selected from Formula A: 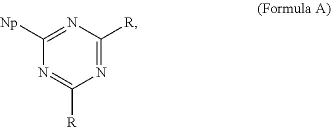
wherein Np is selected from 1-naphthyl or 2-naphthyl, and
wherein each R is independently selected from the following:
i) a (C6-C30)aryl, with or without substituent(s),
ii) a substituted or unsubstituted (C6-C30)aryl fused with one or more (C3-C30)cycloalkyl, with or without substituent(s),
iii) a (C3-C30)heteroaryl with or without substituent(s),
iv) a 5- to 7-membered heterocycloalkyl with or without substituent(s),
v) a substituted or unsubstituted 5- to 7-membered heterocycloalkyl fused with one or more aromatic ring(s),
vi) a (C3-C30)cycloalkyl with or without substituent(s),
vii) a substituted or unsubstituted (C3-C30)cycloalkyl fused with one or more aromatic ring(s),
viii) an adamantyl with or without substituent(s), or
ix) a (C7-C30)bicycloalkyl with or without substituent(s); and
wherein Layer B is formed from a Composition B comprising at least one “HTL compound;” and
wherein Layer A is not adjacent to Layer B.

2. The film of claim 1, wherein, for Formula A, each R is independently selected from the following:
i) a (C6-C30)aryl, with or without substituent(s),
ii) a substituted or unsubstituted (C6-C30)aryl fused with one or more (C3-C30)cycloalkyl, with or without substituent(s),
iii) a (C3-C30)heteroaryl with or without substituent(s),
iv) a 5- to 7-membered heterocycloalkyl with or without substituent(s), or
v) a substituted or unsubstituted 5- to 7-membered heterocycloalkyl fused with one or more aromatic ring(s).

3. The film of claim 1, wherein, for Formula A, each R is independently selected from the following:
i) a (C6-C30)aryl with or without substituent(s), or
ii) a substituted or unsubstituted (C6-C30)aryl fused with one or more (C3-C30)cycloalkyl with or without substituent(s).

4. The film of claim 1, wherein Formula A is selected from the following compounds (a) through (l):

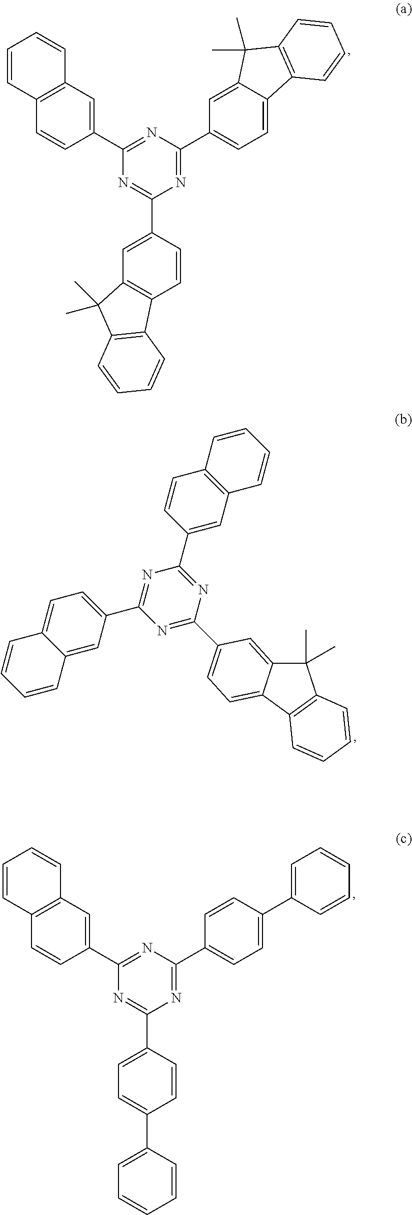 [SMILES: CC1(C)c2ccccc2-c2ccc(-c3nc(-c4ccc5c(c4)C(C)(C)c4ccccc4-5)nc(-c4ccc5ccccc5c4)n3)cc21 ; CC1(C)c2ccccc2-c2ccc(-c3nc(-c4ccc5ccccc5c4)nc(-c4ccc5ccccc5c4)n3)cc21 ; c1ccc(-c2ccc(-c3nc(-c4ccc(-c5ccccc5)cc4)nc(-c4ccc5ccccc5c4)n3)cc2)cc1]

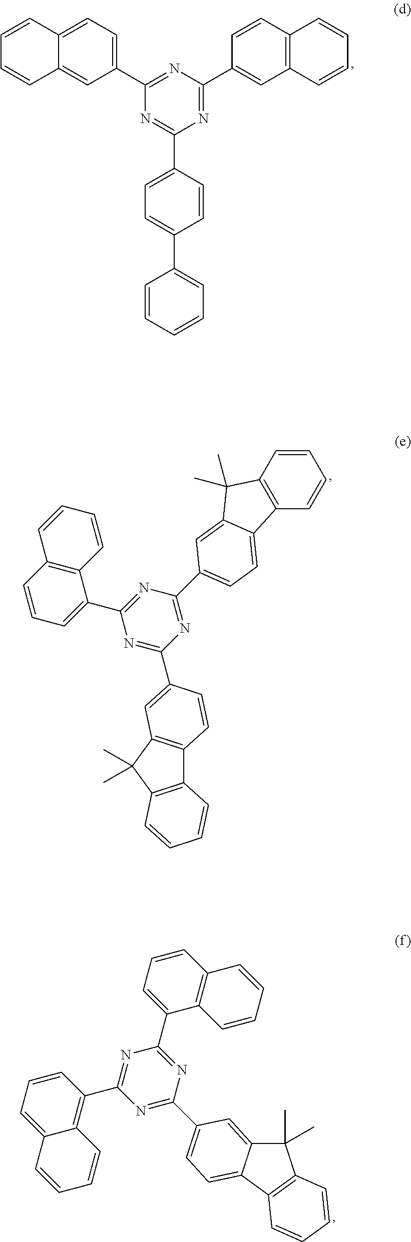 [SMILES: c1ccc(-c2ccc(-c3nc(-c4ccc5ccccc5c4)nc(-c4ccc5ccccc5c4)n3)cc2)cc1 ; CC1(C)c2ccccc2-c2ccc(-c3nc(-c4ccc5c(c4)C(C)(C)c4ccccc4-5)nc(-c4cccc5ccccc45)n3)cc21 ; CC1(C)c2ccccc2-c2ccc(-c3nc(-c4cccc5ccccc45)nc(-c4cccc5ccccc45)n3)cc21]

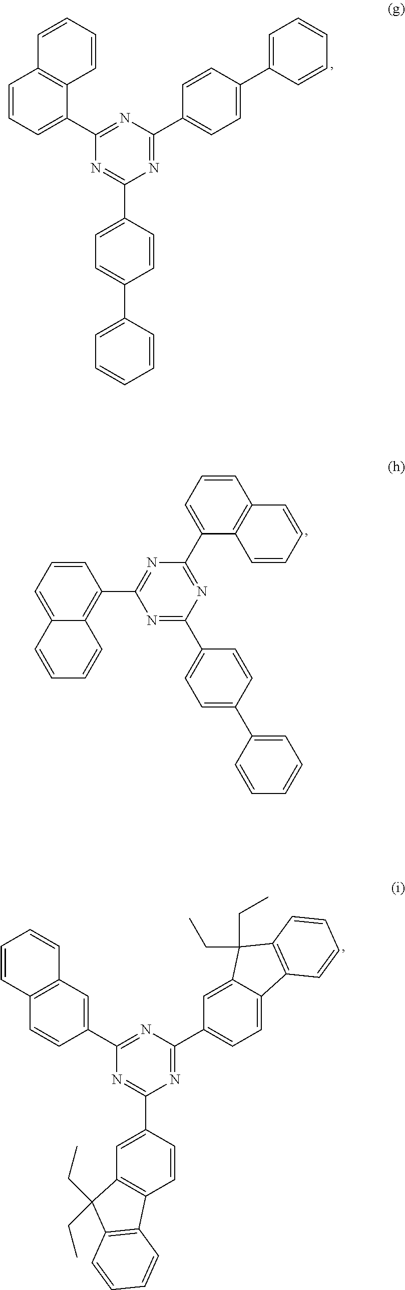 [SMILES: c1ccc(-c2ccc(-c3nc(-c4ccc(-c5ccccc5)cc4)nc(-c4cccc5ccccc45)n3)cc2)cc1 ; c1ccc(-c2ccc(-c3nc(-c4cccc5ccccc45)nc(-c4cccc5ccccc45)n3)cc2)cc1 ; CCC1(CC)c2ccccc2-c2ccc(-c3nc(-c4ccc5c(c4)C(CC)(CC)c4ccccc4-5)nc(-c4ccc5ccccc5c4)n3)cc21]

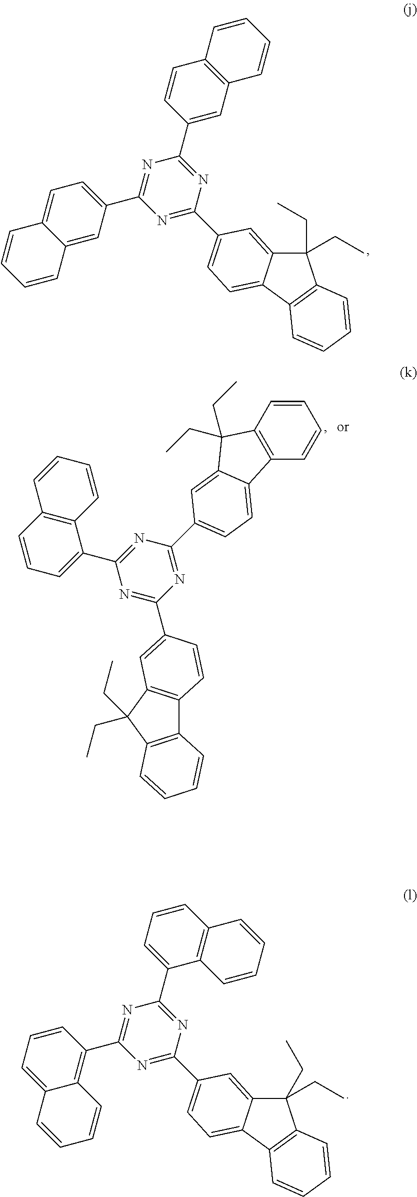 [SMILES: CCC1(CC)c2ccccc2-c2ccc(-c3nc(-c4ccc5ccccc5c4)nc(-c4ccc5ccccc5c4)n3)cc21 ; CCC1(CC)c2ccccc2-c2ccc(-c3nc(-c4ccc5c(c4)C(CC)(CC)c4ccccc4-5)nc(-c4cccc5ccccc45)n3)cc21 ; CCC1(CC)c2ccccc2-c2ccc(-c3nc(-c4cccc5ccccc45)nc(-c4cccc5ccccc45)n3)cc21]

5. The film of claim 1, wherein Composition A further comprises a metal quinolate.

6. An article comprising at least one component formed from the film of any of claim 1.

7. The article of claim 6, wherein the article is an organic electroluminescent device.

8. A composition comprising at least one compound selected from Formula A: 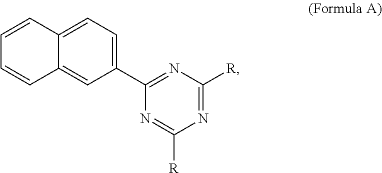
wherein each R is independently selected from the following:
i) a (C6-C30)aryl, with or without substituent(s),
ii) a substituted or unsubstituted (C6-C30)aryl fused with one or more (C3-C30)cycloalkyl, with or without substituent(s),
iii) a (C3-C30)heteroaryl with or without substituent(s),
iv) a 5- to 7-membered heterocycloalkyl with or without substituent(s),
v) a substituted or unsubstituted 5- to 7-membered heterocycloalkyl fused with one or more aromatic ring(s),
vi) a (C3-C30)cycloalkyl with or without substituent(s),
vii) a substituted or unsubstituted (C3-C30)cycloalkyl fused with one or more aromatic ring(s),
viii) an adamantyl with or without substituent(s), or
ix) a (C7-C30)bicycloalkyl with or without substituent(s)
wherein the compound has a Tg greater than, or equal to, 115° C.

9. The composition of claim 8, wherein, for Formula A, each R is independently selected from the following:
i) a (C6-C30)aryl, with or without substituent(s), or
iii) a (C3-C30)heteroaryl with or without substituent(s).

10. The composition of claim 8, wherein, the compound has a Triplet Energy greater than 2.1 eV.

11. The composition of claim 8, wherein the compound is selected from the group consisting of the following:

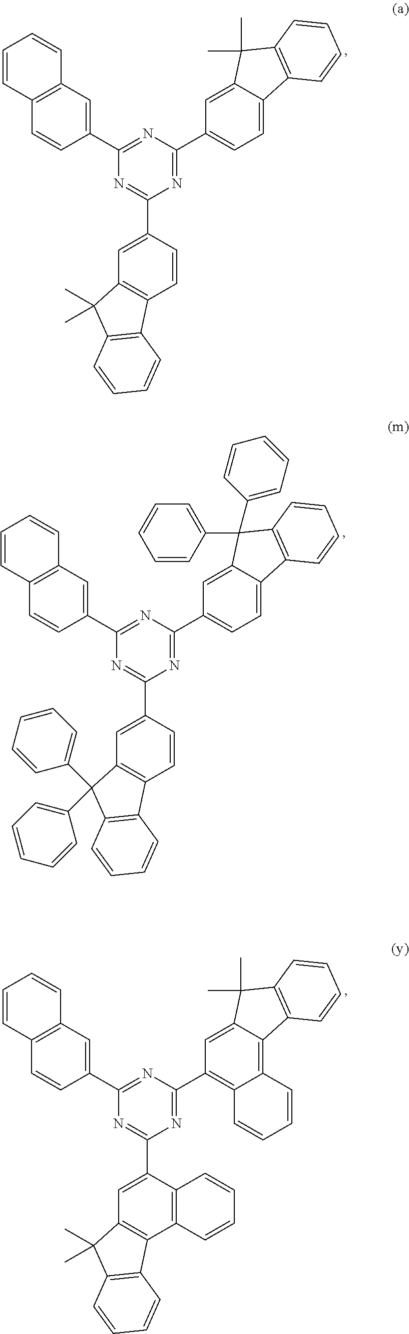 [SMILES: CC1(C)c2ccccc2-c2ccc(-c3nc(-c4ccc5c(c4)C(C)(C)c4ccccc4-5)nc(-c4ccc5ccccc5c4)n3)cc21 ; c1ccc(C2(c3ccccc3)c3ccccc3-c3ccc(-c4nc(-c5ccc6c(c5)C(c5ccccc5)(c5ccccc5)c5ccccc5-6)nc(-c5ccc6ccccc6c5)n4)cc32)cc1 ; CC1(C)c2ccccc2-c2c1cc(-c1nc(-c3ccc4ccccc4c3)nc(-c3cc4c(c5ccccc35)-c3ccccc3C4(C)C)n1)c1ccccc21]

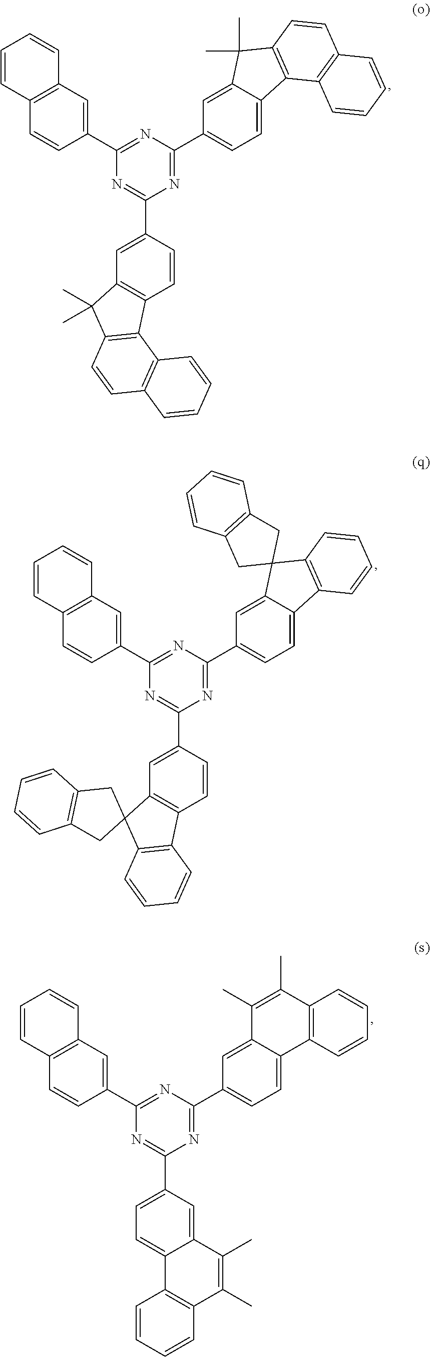 [SMILES: CC1(C)c2cc(-c3nc(-c4ccc5c(c4)C(C)(C)c4ccc6ccccc6c4-5)nc(-c4ccc5ccccc5c4)n3)ccc2-c2c1ccc1ccccc21 ; c1ccc2c(c1)CC1(C2)c2ccccc2-c2ccc(-c3nc(-c4ccc5c(c4)C4(Cc6ccccc6C4)c4ccccc4-5)nc(-c4ccc5ccccc5c4)n3)cc21 ; Cc1c(C)c2cc(-c3nc(-c4ccc5ccccc5c4)nc(-c4ccc5c(c4)c(C)c(C)c4ccccc45)n3)ccc2c2ccccc12]

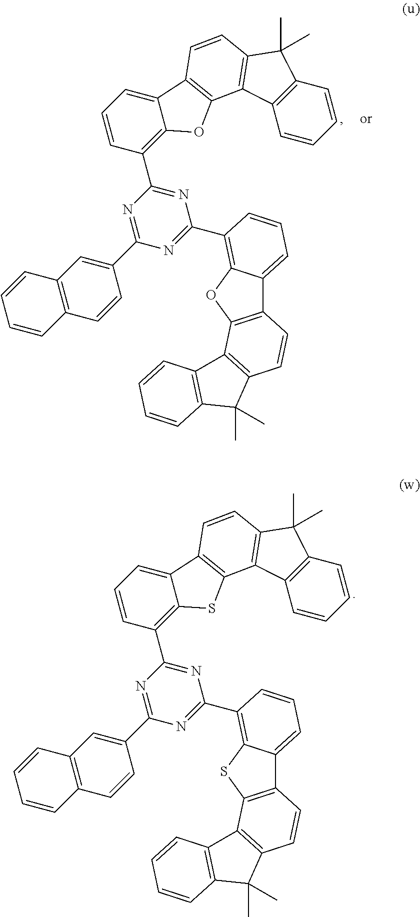 [SMILES: CC1(C)c2ccccc2-c2c1ccc1c2oc2c(-c3nc(-c4ccc5ccccc5c4)nc(-c4cccc5c4oc4c6c(ccc45)C(C)(C)c4ccccc4-6)n3)cccc21 ; CC1(C)c2ccccc2-c2c1ccc1c2sc2c(-c3nc(-c4ccc5ccccc5c4)nc(-c4cccc5c4sc4c6c(ccc45)C(C)(C)c4ccccc4-6)n3)cccc21]

12. The composition of claim 8, further comprises a metal quinolate.

13. A film comprising at least one component formed from the composition of claim 8.

14. An article comprising at least one component formed from the composition of claim 8.

15. The article of claim 14, wherein the article is an organic electroluminescent device.
